(19) United States
(12) Patent Application Publication
(10) Pub. No.: US 2026/0169112 A1
(43) Pub. Date: Jun. 18, 2026

(54) BILATERAL ORTHOGONALITY GENERATIVE ACQUISITIONS

(71) Applicant: THE BOARD OF REGENTS OF THE UNIVERSITY OF TEXAS SYSTEM, Austin, TX (US)

(72) Inventors: Celik Boga, Dallas, TX (US); Anke Henning, Coppell, TX (US)

(21) Appl. No.: 19/383,475

(22) Filed: Nov. 7, 2025

Related U.S. Application Data
(63) Continuation-in-part of application No. PCT/US24/31732, filed on May 30, 2024.
(60) Provisional application No. 63/505,340, filed on May 31, 2023.
(60) Provisional application No. 63/635,605, filed on Apr. 17, 2024.

(51) Int. Cl. G01R 33/56; G01R 33/561; G01R 33/565

(52) U.S. Cl. CPC G01R 33/5608; G01R 33/5605; G01R 33/5614; G01R 33/5659

(57) ABSTRACT

Methods and systems are disclosed for magnetic resonance imaging (MRI), including acquiring a first set of MRI data, including a first MRI scan with first scan parameters using interleaving and a first radiofrequency (RF) mode, and a second MRI scan with the first scan parameters using interleaving and a second RF mode, acquiring a second set of MRI data, including a third MRI scan with second scan parameters using interleaving and a third RF mode, and a fourth MRI scan with the second scan parameters using interleaving and a fourth RF mode, reconstructing a first MRI image and a second MRI image with the first set of MRI data, reconstructing a third MRI image and a fourth MRI image with the second set of MRI data, and generating a combined MRI image from the first MRI image, the second MRI image, the third MRI image, and the fourth MRI image.

### CROSS-REFERENCE TO RELATED APPLICATIONS

This application is a continuation-in-part of International Application No. PCT/US2024/031732, filed May 30, 2024, which claims the benefit of U.S. Provisional Application No. 63/505,340, filed May 31, 2023 and U.S. Provisional Application No. 63/635,605, filed Apr. 17, 2024, each of which is incorporated herein by reference in its entirety for all purposes.

### TECHNICAL FIELD

Aspects of the present disclosure generally relate to systems and methods for magnetic resonance imaging (MRI) and more specifically, systems and methods for generating MRI images with magnetic field effects removed.

### BACKGROUND

Magnetic resonance imaging (MRI) is used for a variety of diagnostic purposes through the generation of one or more images of human anatomy, such as the brain. In connection with MRI imaging, tissue can be characterized by two relaxation times, which help describe how nuclear spins return to equilibrium after being perturbed by a magnetic field. For example, spin-lattice relaxation time or longitudinal relaxation time (T₁) is a time constant for the time that it takes for longitudinal magnetization to recover to its equilibrium value after being perturbed by a radiofrequency (RF) pulse and refers to energy transfer between nuclear spins and the surrounding environment. Spin-spin relaxation or transverse relaxation time (T₂) refers to the time it takes to for transverse magnetization to decay and involves energy transfer between the nuclear spins. In addition, T₂* relaxation is in effect a combination of T₂ relaxation and intravoxel signal dephasing due to microscopic susceptibility differences and respective intravoxel static magnetic field inhomogeneity in Gradient Echo based sequences. Most diagnostic MRI scan protocols include T₁ weighted scans and T₂ and/or T₂* weighted scans, with T₁ weighted images being produced using short echo time (TE) and repetition time (TR) and T₂ and/or T₂* weighted images being produced using longer TE and TR times. A pure T₂ contrast can be obtained by spin-echo sequences, while long TE gradient echo sequences induce a T₂* contrast. In case short TEs and long TRs are combined, the MRI contrast is minimized, and proton density weighted images are obtained.

The T₂* contrast can be used as a diagnostic/prognostic marker in Alzheimer's Disease, Multiple Sclerosis, Parkinson's Disease, Spinal Cord disorders, and other neurological conditions and holds the potential for translation into body and musculoskeletal MRI applications. In addition, the T₂* contrast is in widespread use for functional MRI in neuroscientific research. However, signal losses and field inhomogeneities associated with high field MRI systems ≥3T often result in degraded MRI image quality. For example, transmit field

$$( {B}_{1}^{+} )$$

and main static magnetic field (B₀) inhomogeneities can severely degrade MRI image quality. disclosure

MRI images may be obtained using multichannel transmission systems that utilize coils with various numbers of channels (any channel count higher than 1) to simultaneously transmit the individual radiofrequency (RF) waveforms from each transmission channel. The most common multichannel transmission system is a dual channel system which is available in most 3T and 7T systems. For example, current 3T systems have 2-channel transit systems for better body imaging, and most 7T systems have 2-channel, 8-channel, or even 16-channel systems. Moreover, some 3T and 7T MRI systems also utilize 8 channel multichannel transmission, and 16 channel systems are also available for 7T systems. It is with these observations, among others, that aspects of the present disclosure were conceived and developed.

### SUMMARY

The present disclosure provides methods and systems for magnetic resonance imaging (MRI), in which either

$${T}_{2}^{*}$$

relaxation time weighted images free of artifacts caused by transmit field

$$( {B}_{1}^{+} )$$

and a main static magnetic field (B₀) inhomogeneity are obtained from a combination of three types of separate respective image acquisitions: (I) a circularly polarized (CP) spoiled Gradient Echo (GRE) image using all transmit channels; (II) a second GRE acquisition with additional transmit phase on the first channel or first channel group using all transmit channels; and (Ill) two single-channel acquisitions for each channel (in the case of a two channel transmit system) or channel group (e.g., multiple transmit channels have to be grouped into two groups in case more than 2 transmit channels are available) with shortest possible echo time (TE). Effects based on a transmit magnetic field

$$( {B}_{1}^{+} )$$

and a main static magnetic field (B₀) inhomogeneity are removed from MRI images by generating a corrected homogeneous

$${T}_{2}^{*}$$

magnitude image using a combination of the aforementioned separate images, which is based on the first intermediate combined

$${T}_{2}^{*}$$

image and the second intermediate combined

$${T}_{2}^{*}$$

image and their conjugates. Intermediate images are the set of images obtained by the combination of all four GRE acquisitions, details of the combination will be explained below in Equation 3.

In some aspects, an MRI system includes a superconductive magnet, gradient coils, static magnetic field shim coils, and radiofrequency coils operable to generate varying magnetic fields and a processor to execute instructions stored in a memory that, when executed, cause the system to acquire complex T₂* images with specific aspects using transmit and receive coils. Effects based on a transmit magnetic field

$$( {B}_{1}^{+} )$$

and a main static magnetic field (B₀) inhomogeneity are removed from MRI images by generating a corrected homogeneous T₂* image using a combination of the four aforementioned separate complex images initially acquired from the MRI system.

In some aspects, a non-transitory computer-readable medium includes instructions that, when executed by a computing system, cause the computing system to acquire complex

$${T}_{2}^{*}$$

weighted images with specific aspects using transmit and receive coils. Effects based on a transmit magnetic field

$$( {B}_{1}^{+} )$$

and a main static magnetic field (B₀) inhomogeneity are removed from MRI images by generating a corrected homogeneous

$${T}_{2}^{*}$$

image using a combination of the four aforementioned separate complex images initially acquired from the MRI system. Other implementations are also described and recited herein. Further, while multiple implementations are disclosed, still other implementations of the present disclosure will become apparent to those skilled in the art from the following detailed description, which shows and describes illustrative implementations of the present disclosure. As will be realized, the present disclosure is capable of modifications in various aspects, all without departing from the spirit and scope of the present disclosure. Accordingly, the drawings and detailed description are to be regarded as illustrative in nature and not limiting.

In some aspects, the techniques described herein relate to a method of reducing artifacts in MRI images, the method including: acquiring a first set of MRI data including a first MRI scan with first scan parameters using interleaving and a first radiofrequency (RF) mode, and a second MRI scan with the first scan parameters using interleaving and a second RF mode; acquiring a second set of MRI data including a third MRI scan with second scan parameters using interleaving and a third RF mode, and a fourth MRI scan with the second scan parameters using interleaving and a fourth RF mode; reconstructing a first MRI image S₁ and a second MRI image S₂ with the first set of MRI data; reconstructing a third MRI image S₃ and a fourth MRI image S₄ with the second set of MRI data; and generating a combined MRI image from the first MRI image S₁, the second MRI image S₂, the third MRI image S₃, and the fourth MRI image S₄.

In some aspects, the techniques described herein relate to a method, wherein the generating of the combined MRI image from the first set of MRI data and the second set of MRI data includes: generating a pair of intermediate images using the first MRI image S₁, the second MRI image S₂, the third MRI image S₃, and the fourth MRI image S₄ to combine the first set of MRI data and the second set of MRI data, wherein the pair of intermediate images is generated to have a bilateral orthogonality relation; and generating the combined MRI image from the pair of intermediate images.

In some aspects, the techniques described herein relate to a method, wherein the first RF mode is a same mode as the third RF mode, the second RF mode is a same mode as the fourth RF mode, the first RF mode is different from the second RF mode, and the third RF mode is different from the fourth RF mode.

In some aspects, the techniques described herein relate to a method, wherein an MRI mode and pulse sequence used for acquiring the first set of MRI data and the second set of MRI data is selected from the group consisting of balanced steady state free precession (bSSFP) MRI imaging and Chemical exchange saturation transfer (CEST) imaging.

In some aspects, the techniques described herein relate to a method, wherein estimations are calculated as

$${E}_{1}^{n , i} / {E}_{1}^{d , i} = {e}^{- T R / {T}_{1}} , {E}_{2}^{n , i} / {E}_{2}^{d , i} = {e}^{- T R / {T}_{2}} ,$$

proton density is calculated as PD^{n,i}/PD^{d,i}=PD, where n or d indicates numerator or denominator and i indicates an RF mode.

In some aspects, the techniques described herein relate to a method, wherein first MRI image S₁, the second MRI image S₂, the third MRI image S₃, and the fourth MRI image S₄ are reconstructed as S₁=a^{n,1}, S₂=a^{n,2}, S₃=0.5(a^{n,1}−a^{n,2}) and S₄=0.5(a^{n,1}+a^{n,2}), where a may be either E₁, E₂ or PD.

In some aspects, the techniques described herein relate to a method, wherein the generating of the combined image includes: calculating a pair of intermediary results as

$${C}_{1} = {S}_{3}^{*} {S}_{1} + {S}_{4} {S}_{2}^{*} and {C}_{2} = {S}_{4}^{*} {S}_{1} - {S}_{3} {S}_{2}^{*} ;$$

and calculating the combined image as I=0.5 \sqrt{(|C₁|²+|C₂|²)}/(|S₃|²+|S₄|²).

In some aspects, the techniques described herein relate to a method, wherein the generating of the combined image I includes: calculating virtual single-channel acquisition images as

$${S}_{1} = 0.5 ( {S}_{R {F}_{1}}^{ref} - {S}_{R {F}_{2}}^{ref} ) and {S}_{2} = 0.5 ( {S}_{R {F}_{1}}^{ref} + {s}_{R {F}_{2}}^{ref} ) ;$$

calculating a pair of intermediary results as

$${C}_{1} = {S}_{R {F}_{1}}^{i} {S}_{1} + {S}_{R {F}_{2}}^{i} {S}_{2} and {C}_{2} = {S}_{R {F}_{2}}^{i} {S}_{1} - {S}_{R {F}_{1}}^{i} {S}_{2} ;$$

and calculating the combined image I=0.5\sqrt{(|C₁|²+|C₂|²)}/(|S₃|²+|S₄|²).

In some aspects, the techniques described herein relate to a method, wherein the generating of the combined image I includes: calculating a first intermediary result as

$${C}_{1} = {S}_{R {F}_{1}}^{i} {S}_{1} + {S}_{R {F}_{2}}^{i} {S}_{2} ,$$

calculating a second intermediary result as

$${C}_{2} = {S}_{R {F}_{2}}^{i} {S}_{1} - {S}_{R {F}_{1}}^{i} {S}_{2} ,$$

and calculating the combined image as I=0.5 \sqrt{(|C₁|²+|C₂|²)}/(|S₃|²+|S₄|²).

In some aspects, the techniques described herein relate to a method, wherein the interleaving is phase-cycled interleaving, and the first set of MRI data is acquired with phases corresponding to odd-indexed phases and the second set of MRI data is acquired with phases corresponding to even-indexed phases. In some aspects, the techniques described herein relate to a method, wherein the interleaving is offset interleaving, and the first MRI data set is acquired with odd numbered offsets and the second MRI data is acquired with even numbered offsets.

In some aspects, the techniques described herein relate to a computing apparatus including: a processor; and a memory storing instructions that, when executed by the processor, configure the apparatus to: acquire a first set of MRI data including a first MRI scan with first scan parameters using interleaving and a first radiofrequency (RF) mode, and a second MRI scan with the first scan parameters using interleaving and a second RF mode; acquire a second set of MRI data including a third MRI scan with second scan parameters using interleaving and a third RF mode, and a fourth MRI scan with the second scan parameters using interleaving and a fourth RF mode; reconstruct a first MRI image S₁ and a second MRI image S₂ with the first set of MRI data; reconstruct a third MRI image S₃ and a fourth MRI image S₄ with the second set of MRI data; and generate a combined MRI image from the first MRI image S₁, the second MRI image S₂, the third MRI image S₃, and the fourth MRI image S₄.

In some aspects, the techniques described herein relate to a computing apparatus, wherein the generating of the combined MRI image from the first set of MRI data and the second set of MRI data includes: generating a pair of intermediate images using the first MRI image S₁, the second MRI image S₂, the third MRI image S₃, and the fourth MRI image S₄ to combine the first set of MRI data and the second set of MRI data, wherein the pair of intermediate images is generated to have a bilateral orthogonality relation; and generating the combined MRI image from the pair of intermediate images.

In some aspects, the techniques described herein relate to a computing apparatus, wherein an MRI mode and pulse sequence used for acquiring the first set of MRI data and the second set of MRI data is selected from the group consisting of balanced steady state free precession (bSSFP) MRI imaging and Chemical exchange saturation transfer (CEST) imaging.

In some aspects, the techniques described herein relate to a computing aparatus, wherein estimations are calculated as

$${E}_{1}^{n , i} / {E}_{1}^{d , i} = {e}^{- T R / {T}_{1}} , {E}_{2}^{n , i} / {E}_{2}^{d , i} = {e}^{- T R / {T}_{2}} ,$$

and proton density is calculated as PD^{n,i}L/PD^{d,i}=PD, where n or d indicates numerator or denominator and i indicates an RF mode.

In some aspects, the techniques described herein relate to a computing apparatus, wherein the first MRI image S₁, the second MRI image S₂, the third MRI image S₃, and the fourth MRI image S₄ are reconstructed as S₁=a^{n,1}, S₂=a^{n,2}, S₃=0.5(a^{n,1}-a^{n,2}) and S₄=0.5(a^{n,1}+a^{n,2}), where a may be either E₁, E₂ or PD.

In some aspects, the techniques described herein relate to a computing apparatus, wherein the generating of the combined image includes: calculating a pair of intermediary results as

$${C}_{1} = {S}_{3}^{*} {S}_{1} + {S}_{4} {S}_{2}^{*} and {C}_{2} = {S}_{4}^{*} {S}_{1} - {S}_{3} {S}_{2}^{*} ;$$

and calculating the combined image as I=0.5 \sqrt{(|C₁|²+|C₂|²)}/(|S₃|²+|S₄|²).

In some aspects, the techniques described herein relate to a computing apparatus, wherein the generating of the combined image I includes: calculating virtual single-channel acquisition images as

$${S}_{1} = 0.5 ( {S}_{R {F}_{1}}^{ref} - {s}_{R {F}_{2}}^{ref} ) and {S}_{2} = 0.5 ( {S}_{R {F}_{1}}^{ref} + {s}_{R {F}_{2}}^{ref} ) ;$$

calculating a pair of intermediary results as

$${C}_{1} = {S}_{R {F}_{1}}^{i} {S}_{1} + {S}_{R {F}_{2}}^{i} {S}_{2} and {C}_{2} = {S}_{R {F}_{2}}^{i} {S}_{1} - {S}_{R {F}_{1}}^{i} {S}_{2} ;$$

and calculating the combined image I=0.5 \sqrt{(|C₁|²+IC₂|²)}/(|S₃|²+|S₄|²).

In some aspects, the techniques described herein relate to a computing apparatus, wherein the generating of the combined image I includes: calculating a first intermediary result as

$${C}_{1} = {S}_{R {F}_{1}}^{i} {S}_{1} + {S}_{R {F}_{2}}^{i} {S}_{2} ,$$

calculating a second intermediary result as

$${C}_{2} = {S}_{R {F}_{2}}^{i} {S}_{1} - {S}_{R {F}_{1}}^{i} {S}_{2} ,$$

and calculating the combined image as I=0.5 \sqrt{(|C₁|²+|C₂|²)}/(|S₃|²+|S₄|²).

In some aspects, the techniques described herein relate to a computing apparatus, wherein the interleaving is phase-cycled interleaving, and the first set of MRI data is acquired with phases corresponding to odd-indexed phases and the second set of MRI data is acquired with phases corresponding to even-indexed phases.

In some aspects, the techniques described herein relate to a computing apparatus, wherein the interleaving is offset interleaving, and the first MRI data set is acquired with odd-numbered offsets and the second MRI data is acquired with even-numbered offsets.

In some aspects, the techniques described herein relate to a non-transitory computer-readable storage medium, the computer-readable storage medium including instructions that when executed by a computer, cause the computer to: acquire a first set of MRI data including a first MRI scan with first scan parameters using interleaving and a first radiofrequency (RF) mode, and a second MRI scan with the first scan parameters using interleaving and a second RF mode; acquire a second set of MRI data including a third MRI scan with second scan parameters using interleaving and a third RF mode, and a fourth MRI scan with the second scan parameters using interleaving and a fourth RF mode; reconstruct a first MRI image S₁ and a second MRI image S₂ with the first set of MRI data; reconstruct a third MRI image S₃ and a fourth MRI image S₄ with the second set of MRI data; and generate a combined MRI image from the first MRI image S₁, the second MRI image S₂, the third MRI image S₃, and the fourth MRI image S₄.

### BRIEF DESCRIPTION OF THE DRAWINGS

In order to describe the manner in which the above-recited and other advantages and features of the disclosure can be obtained, a more particular description of the principles briefly described above will be rendered by reference to specific implementations thereof which are illustrated in the appended drawings. Understanding that these drawings depict only example implementations of the disclosure and are not therefore to be considered to be limiting of its scope, the principles herein are described and explained with additional specificity and detail through the use of the accompanying drawings in which:

FIG. 1 illustrates representative transversal slices in magnetic resonance imaging (MRI) images of three volunteers, in accordance with an example implementation.

FIG. 2A illustrates representative MRI images of a first volunteer in the transversal direction, in accordance with an example implementation.

FIG. 2B illustrates representative MRI images of a second volunteer in the transversal direction, in accordance with an example implementation.

FIG. 3A illustrates representative MRI images of a first volunteer in the coronal direction, in accordance with an example implementation.

FIG. 3B illustrates representative MRI images of a second volunteer in the coronal direction, in accordance with an example implementation.

FIG. 4A illustrates representative MRI images of a first volunteer in the sagittal direction, in accordance with an example implementation.

FIG. 4B illustrates representative MRI images of a second volunteer in the sagittal direction, in accordance with an example implementation.

FIG. 5A illustrates a first high-resolution image comparison for a third volunteer, in accordance with an example implementation.

FIG. 5B illustrates a second high-resolution image comparison for a third volunteer, in accordance with an example implementation.

FIG. 5C illustrates a third high-resolution image comparison for a third volunteer, in accordance with an example implementation.

FIG. 6 illustrates comparison of magnitude of the final

$${T}_{2}^{*}$$

images obtained using the bilateral orthogonality method, the ratio of two GRE images, and the percentage ratio of the aforementioned final images, in accordance with an example implementation.

FIG. 7A illustrates a graphical comparison of noise power for homogeneous transversal

$${T}_{2}^{*}$$

images.

FIG. 7B illustrates a graphical comparison of noise power for homogeneous transversal

$${T}_{2}^{*}$$

images.

FIG. 7C illustrates a graphical comparison of noise power for homogeneous transversal

$${T}_{2}^{*}$$

images.

FIG. 8A illustrates 4×4 groupings and corresponding transmission angles resulting from an image acquisition, in accordance with an example implementation.

FIG. 8B illustrates 5×3 groupings and corresponding transmission angles resulting from an image acquisition, in accordance with an example implementation.

FIG. 9A illustrates a circularly polarized (CP) mode

$${T}_{2}^{*}$$

image acquired from a center transversal slice, in accordance with an example implementation for an 8-channel system.

FIG. 9B illustrates a final

$${T}_{2}^{*}$$

image obtained via a ratio of two GRE acquisitions and CP mode

$${T}_{2}^{*}$$

image from the center transversal slice, in accordance with an example implementation for an 8-channel system.

FIG. 9C illustrates

$${T}_{2}^{*}$$

images obtained via bilateral orthogonality generating acquisitions method for the channel grouping combinations provided in FIG. 8A, in accordance with an example implementation for an 8-channel system.

FIG. 9D illustrates

$${T}_{2}^{*}$$

images obtained via bilateral orthogonality generating acquisitions method for the channel grouping combinations provided in FIG. 8B, in accordance with an example implementation for an 8-channel system.

FIG. 10 illustrates a system to implement the Bilateral Orthogonality Generating Acquisitions method, in accordance with some example implementations.

FIG. 11 illustrates a flow diagram for a method to implement the Bilateral Orthogonality Generating Acquisitions method, in accordance with some example implementations.

FIG. 12 illustrates example MRI images produced by applying the Bilateral Orthogonality Generating Acquisitions Method to MRI images acquired using balanced steady state free precession (bSSFP) MRI imaging, in accordance with some example implementations.

FIG. 13 illustrates example MRI images produced by applying the Bilateral Orthogonality Generating Acquisitions Method to MRI images acquired using multi echo gradient echo (GRE) MRI imaging, in accordance with some example implementations.

FIG. 14 illustrates example MRI images produced by applying the Bilateral Orthogonality Generating Acquisitions Method to MRI images acquired using fluid attenuated inversion recovery (FLAIR) MRI imaging, in accordance with some example implementations.

FIG. 15 illustrates example MRI images produced by applying the Bilateral Orthogonality Generating Acquisitions Method to MRI images acquired using spin echo (SE) MRI imaging, in accordance with some example implementations.

FIG. 16A illustrates example S2 MRI images of a kidney for Dixon imaging using Bilateral Orthogonality Generating Acquisitions Method, in accordance with some example implementations.

FIG. 16B illustrates example S1 MRI images of a kidney for Dixon imaging using Bilateral Orthogonality Generating Acquisitions Method, in accordance with some example implementations.

FIG. 17A illustrates an example of an S3 MRI image of a kidney for Dixon imaging using Bilateral Orthogonality Generating Acquisitions Method, in accordance with some example implementations.

FIG. 17B illustrates an example of an S4 MRI images of a kidney for Dixon imaging using Bilateral Orthogonality Generating Acquisitions Method, in accordance with some example implementations.

FIG. 17C illustrates an example of a water mask of a kidney for Dixon imaging, in accordance with some example implementations.

FIG. 17D illustrates an example of a fat mask of a kidney for Dixon imaging, in accordance with some example implementations.

FIG. 18 illustrates example

$${T}_{2}^{*}$$

weighted contrast MRI images produced by applying the Bilateral Orthogonality Generating Acquisitions Method to the MRI images shown in FIGS. 16A-B and 17A-B, in accordance with some example implementations.

FIG. 19 illustrates example water and fat images generated using Dixon imaging for the MRI images shown in FIGS. 16A-B and 17A-B, in accordance with some example implementations.

FIG. 20 illustrates another flow diagram for a method to implement the Bilateral Orthogonality Generating Acquisitions method using balanced steady state free precession (bSSFP) with interleaving, in accordance with some example implementations.

FIG. 21 illustrates another flow diagram for a method to implement the Bilateral Orthogonality Generating Acquisitions method using Chemical exchange saturation transfer (CEST) with interleaving, in accordance with some example implementations.

FIG. 22A illustrates example MRI images produced by applying the Bilateral Orthogonality Generating Acquisitions Method to MRI images acquired using balanced steady state free precession (bSSFP) MRI imaging with interleaving, in accordance with some example implementations.

FIG. 22B illustrates another example of MRI images produced by applying the Bilateral Orthogonality Generating Acquisitions Method to MRI images acquired using the bSSFP MRI imaging with interleaving, in accordance with some example implementations.

FIG. 23 illustrates example MRI images produced by applying the Bilateral Orthogonality Generating Acquisitions Method to MRI images acquired using Chemical exchange saturation transfer (CEST) MRI imaging with interleaving, in accordance with some example implementations.

FIG. 24 illustrates a computing system that implements the Bilateral Orthogonality Generating Acquisitions Method, in accordance with some example implementations.

FIG. 25 illustrates another computing system that implements the Bilateral Orthogonality Generating Acquisitions Method, in accordance with some example implementations.

It will be apparent to one skilled in the art after review of the entirety disclosed that the steps illustrated in the figures listed above may be performed in other than the recited order, and that one or more steps illustrated in these figures may be optional.

### DETAILED DESCRIPTION

Various implementations of the disclosure are discussed in detail below. While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described to avoid obscuring the description. References to one or an implementation in the present disclosure can be references to the same implementation or any implementation; and such references mean at least one of the implementations.

Reference to “one implementation” or “an implementation” means that a particular feature, structure, or characteristic described in connection with the implementation is included in at least one implementation of the disclosure. The appearances of the phrase “in one implementation” in various places in the specification are not necessarily all referring to the same implementation, nor are separate or alternative implementations mutually exclusive of other implementations. Moreover, various features are described which may be exhibited by some implementations and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various implementations given in this specification.

Without intent to limit the scope of the disclosure, examples of instruments, apparatus, methods, and their related results according to the implementations of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

Generally, the present disclosure eliminates or otherwise significantly reduces signal losses and field inhomogeneities for

$${T}_{2}^{*}$$

weighted MRI, including transmit field and main static magnetic field inhomogeneity, to increase magnetic resonance imaging (MRI) image quality and/or address the shortcomings of conventional

$${T}_{2}^{*}$$

weighted MRI as well as limitations of various techniques that have been previously suggested to mitigate transmit field and main static magnetic field inhomogeneity effects. Previously introduced methods, such as magnetization prepared rapid gradient echo (MPRAGE) sequence or its variation MP2RAGE, may be used for T₁ weighted images using a combination of two consecutive spoiled Gradient Echo (GRE) acquisitions with different inversion times. While the MP2RAGE sequence may be used to address the transmit field inhomogeneity in the resulting images, it cannot be extended to other contrasts including the herein described

$${T}_{2}^{*}$$

weighted MRI. As another example for eliminating the signal loss due to transmit field inhomogeneity, time-interleaved acquisition of modes (TIAMO) obtains images using a first mode with 45° phase increments between channels that are combined with images obtained via another mode with 90° phase increments between channels. TIAMO effectively eliminates the signal losses for various contrasts. However, transmit field inhomogeneity due to high intensity regions still remain in the reconstructed images. Additionally, radiofrequency (RF) pulse design may be used for the mitigation of main and transmit field inhomogeneities in parallel transmission (pTx) systems. However, design of the RF pulses requires a priori measurement of

$${B}_{1}^{+}$$

and B₀ maps resulting in an increase in total scan time. To avoid increasing scan time, Universal Pulses were introduced. In the Universal Pulses technique, pulses are designed based on a database of

$${B}_{1}^{+}$$

and ΔB₀ measurements, so that designed pulses can be used for all scans without additional

$${B}_{1}^{+}$$

and ΔB₀ measurements. While these methods provide robust solutions against transmit inhomogeneities, they require significant amount of a priori scans and substantial computation time either before or during each scan session and several pulses have to be designed for in accordance with various applications. Homogeneous

$${T}_{2}^{*}$$

weighted images can be obtained by the ratio of the two GRE images with different echo times. However, the resulting images can be affected from noise enhancement at the low signal intensity regions.

Accordingly, the present disclosure is directed to systems and methods for removing effects based on a transmit magnetic field

$$( {B}_{1}^{+} )$$

and main static magnetic field (ΔB₀) inhomogeneity in

$${T}_{2}^{*}$$

weighted MRI imaging. A parallel transmission (pTx) system with two or more independent radiofrequency transmission channels can generate a corrected homogeneous

$${T}_{2}^{*}$$

weighted image using a combination of four separate image acquisitions: (I) a circularly polarized (CP) spoiled Gradient Echo (GRE) image using all transmit channels; (II) a second GRE acquisition with additional transmit phase on a first channel or first channel group using all transmit channels; and (Ill) two single-channel acquisitions for each channel (in case of a two channel transmit system) or channel group (multiple transmit channels have to be grouped into two groups in the case of more than 2 transmit channels being available).

More particularly, systems and methods are described herein for generating homogeneous

$${T}_{2}^{*}$$

contrast images for parallel transmission human 3T and 7T MRI systems, utilizing an application of a technique (e.g., a bilateral orthogonality generating acquisitions method) in which two (or several channels grouped in two) transmit channels are used, where two acquisitions using all transmission channels and two single-channel acquisitions (or two groups of transmission channels in the case of more than two transmission channels being used) are used to acquire two intermediate

$${T}_{2}^{*}$$

images. Some techniques of the present disclosure are based on fixed flip angles, to ensure the same contrast on all acquired images. Finally,

$${T}_{2}^{*}$$

images can be calculated by the ratio of a combination of the intermediate images obtained using the technique and the square sum of the magnitudes of the single-channel acquisitions.

Multiple transmit channels are used to acquire images in a circularly polarized (CP) mode with and without additional transmit phase for the first channel. Effects based on a transmit magnetic field

$$( {B}_{1}^{+} )$$

and main static magnetic field (ΔB₀) inhomogeneity may be removed from the final image by the ratio of a combination of the intermediate images obtained using the technique and the square sum of the magnitudes of the single-channel acquisitions.

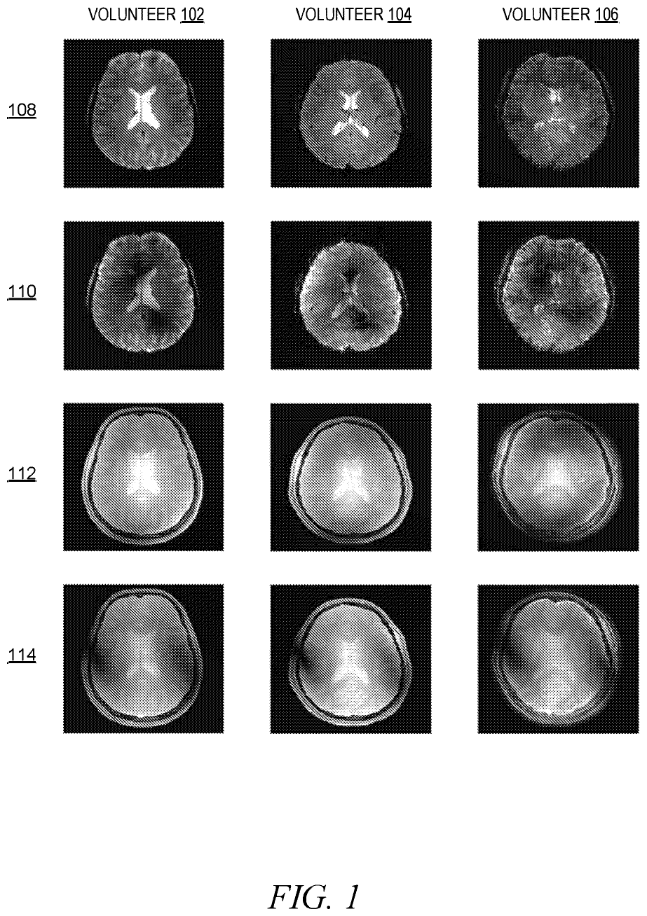

To illustrate the techniques disclosed herein, reference is made to FIG. 1, which illustrates representative transversal slices in MRI input images of three volunteers: volunteer 102, volunteer 104, and volunteer 106. In the example implementation, a plurality of images is received that includes a first set of images and a second set of images, where the first set of images are small angle spoiled Gradient Echo (GRE), and the second set of images are single-channel GRE images with shorter echo time (TE) and a same flip angle as the first set of images. Orthogonality is generated bilaterally based on an adjustment of transmit phases in the first set of images, and a combination of the first set of images and the second set of images. In the example implementation, a total of four data acquisitions with the same flip angle are included as part of the proposed method, where the first two acquisitions are small angle spoiled GRE acquisitions with predetermined additional transmit phases, and the last two acquisitions are single-channel GRE acquisitions with shorter echo time (TE) and the same flip angle as in the first two acquisitions, resulting in a homogeneous T₂* contrast image with effective echo time (TE_{eff}).

For example, in the example implementation shown, a first set of images corresponds to circularly polarized (CP) mode acquisition—e.g., row 108 shows GRE images for volunteer 102, volunteer 104, and volunteer 106 acquired in CP mode (S₁). Row 110 shows GRE images for volunteer 102, volunteer 104, and volunteer 106 acquired with channel 1 having an additional transmit phase of π (S₂). Row 112 shows GRE images of single-channel acquisition for channel 1 (S₃) and row 114 shows GRE images of single-channel acquisition for channel 2 (S₄). In some implementations, all images are magnitude images of spoiled GRE acquisitions using a 7T dual channel TX MRI system and show transversal slice 50 for volunteer 102 and volunteer 104, and transversal slice 155 for volunteer 106.

In some implementations, orthogonality can be generated bilaterally by both the adjustment of additional transmit phases, as explained in [0056], in the first two acquisitions (e.g., rows 108, 110) and the combination of all 4 acquisitions, and thus the proposed method is designated as the Bilateral Orthogonality Generating Acquisitions method. It is demonstrated that homogeneous contrast T₂* images can be obtained without the requirement for prior mapping of

$$Δ {B}_{1}^{+}$$

and ΔB₀. Comparison between the ratio of GRE images with different echo times can also be utilized, where the ratio method can also result in homogeneous contrast with the same effective echo time.

In some example implementations corresponding to bilateral orthogonality generating acquisitions, for example in a dual channel pTx system, flip angle at a single pixel, can be calculated as α=(s₁e^{jθ}^{₁}β+s₂e^{jη}^{₂}β)e^{jφ} using small tip angle approximation. Where β and φ denote the magnitude and angle of the complex flip angle, sₙ, is the channel sensitivity and θₙ is the transmission phase for channel n. By defining

$${q}_{n} = {s}_{n} {e}^{j {θ}_{n}} {e}^{\frac{j ϕ}{2}} ,$$

flip angle can be calculated as α=(q₁+q₂)β.

The spoiled GRE signal equation can be written as in Equation 1(a) (below) and with small angle approximation, where flip angle α<10°, effects of T₁ relaxation and repetition time (TR) can be eliminated for obtaining small angle GRE signal equation in Equation 1(b). In Equations 1(a,b), ρ is the proton density,

$${E}_{1} = {e}^{- \frac{TR}{{T}_{1}}} and {E}_{2}^{*} = {e}^{- \frac{TE}{{T}_{2}^{*}}} . \qquad 1 ( a )$$

$${S}_{G R E} = \frac{ρ sin α ( 1 - {E}_{1} ) {E}_{2}^{*}}{( 1 - cos α {E}_{1} )}$$

$${S}_{GRE , SA} = ρ α {E}_{2}^{*} \qquad 1 ( b )$$

The scan time is significantly reduced by using small angle GRE equation in Equation 1 to eliminate the dependency on T₁ and repetition time (TR). Moreover, for a dual channel pTx system, the spoiled GRE signal can be further written as

$$S = ρ {E}_{2}^{*} ( {q}_{1} + {q}_{2} ) β$$

with the aforementioned flip angle conditions.

According to certain non-limiting examples, the first two input images are defined as

$${S}_{1} = ρ {E}_{2 , 1}^{*} ( {q}_{1} + {q}_{2} ) β and {S}_{2} = ρ {E}_{2 , 1}^{*} ( - {q}_{1} + {q}_{2} ) {β}^{*}$$

with TE₁ for generating the initial T₂ contrast. S₁ corresponds to the circularly polarized (CP) mode acquisition. Since the transmit phase of the pulses is included in θ_{1,2}, β defines only the real valued amplitude of the pulse resulting in β*, which then leads to

$${S}_{2} = ρ {E}_{2 , 1}^{*} ( - {q}_{1} + {q}_{2} ) β$$

for the second acquisition. The negative flip angle is implemented via the additional transmit phase of π for the first channel.

The last two acquisitions utilize the same pulses with shortest possible TE₂ for minimal effect on the TE_{eff}=TE₂−TE₁ and shortest TR and thus fastest possible scan time, but channels are used individually, resulting in

$${S}_{3 , 4} = ρ {E}_{2 , 2}^{*} {q}_{1 , 2} β .$$

By combining the four signals, C₁ and C₂ can be defined as

$${C}_{1} = {S}_{3}^{*} {S}_{1} + {S}_{4} {S}_{2}^{*} and {C}_{2} = {S}_{4}^{*} {S}_{1} - {S}_{3} {S}_{2}^{*} .$$

In matrix format, combined signals can be written as in Equation 2.

$$C = [ \begin{matrix}{C}_{1} \\ {C}_{2}\end{matrix} ] = {ρ}^{2} {E}_{2 , 1}^{*} {E}_{2 , 2}^{*} [ \begin{matrix}{q}_{1}^{*} β & {q}_{2} β \\ {q}_{2}^{*} β & - {q}_{1} β\end{matrix} ] [ \begin{matrix}{q}_{1} & {q}_{2} \\ {q}_{2}^{*} & - {q}_{1}^{*}\end{matrix} ] [ \begin{matrix}β \\ β\end{matrix} ] = {ρ}^{2} {E}_{2 , 1}^{*} {E}_{2 , 2}^{*} {β}^{2} [ \begin{matrix}{\vert {q}_{1} \vert}^{2} + {\vert {q}_{2} \vert}^{2} \\ {\vert {q}_{1} \vert}^{2} + {\vert {q}_{2} \vert}^{2}\end{matrix} ] \qquad ( 2 )$$

In some implementations, a combination of a magnitude of the first channel (C₁) and a magnitude of the second channel (C₂) eliminates distortions caused by phase mismatches. Equation 2 can be obtained via both the additional transmit phase of π and the combination of all 4 GRE acquisitions. Matrices in Equation 2 are only orthogonal complex square matrices and resulting C₁ and C₂ are orthogonal because of this. There may be variance in orthogonality based on the individual phase alteration in each acquisition due to off-resonance effects. In Equation 3, the effect of the total phase mismatch is shown with total phase mismatch for C₁ and C₂ denoted as δ₁ and δ₂. Because receive channel combination aims to achieve uniform receive sensitivity, magnitude effects of the receive channels are assumed to be the same for all acquisitions and are not shown in Equation 3.

$$C = [ \begin{matrix}{C}_{1} \\ {C}_{2}\end{matrix} ] = [ \begin{matrix}{S}_{3}^{*} & {S}_{4} \\ {S}_{4}^{*} & - {S}_{3}\end{matrix} ] [ \begin{matrix}{S}_{1} \\ {S}_{2}^{*}\end{matrix} ] = [ \begin{matrix}{q}_{1}^{*} β & {q}_{2} β \\ {q}_{2}^{*} β & - {q}_{1} β\end{matrix} ] [ \begin{matrix}{e}^{i γ} & 0 \\ 0 & {e}^{- i γ}\end{matrix} ] [ \begin{matrix}{q}_{1} & {q}_{2} \\ {q}_{2}^{*} & - {q}_{1}^{*}\end{matrix} ] [ \begin{matrix}β \\ β\end{matrix} ] = {ρ}^{2} {E}_{2 , 1}^{*} {E}_{2 , 2}^{*} {β}^{2} [ \begin{matrix}{\vert {q}_{1} \vert}^{2} {e}^{i γ} + {\vert {q}_{2} \vert}^{2} {e}^{- i γ} + ( {e}^{i γ} - {e}^{- i γ} ) {q}_{1}^{*} {q}_{2} \\ {\vert {q}_{1} \vert}^{2} {e}^{i γ} + {\vert {q}_{2} \vert}^{2} {e}^{- i γ} + ( {e}^{i γ} - {e}^{- i γ} ) {q}_{1} {q}_{2}^{*}\end{matrix} ] \qquad ( 3 )$$

Because the orthogonality of C₁ and C₂ is only valid if there is no phase mismatch (δ₁=δ₂) between transmit and receive channels, both C₁ and C₂ contains cross terms leading to distortions in final

$${T}_{2}^{*}$$

images. In order to provide robustness against phase mismatches, the magnitudes of C₁ and C₂ are combined to eliminate cross terms in C₁ and C₂ arising from a lack of orthogonality, before obtaining the final

$${T}_{2}^{*}$$

image. Final whole brain

$${T}_{2}^{*}$$

images with effective echo time of TE_{eff}=TE₁−TE₂, which will be denoted I, are calculated using the ratio of square root of magnitude summation of C₁ and C₂ and magnitude summation of S₃ and S₄ as

$$I = \sqrt{0.5 {C}^{H} C} / ( {S}_{3}^{*} {S}_{3} + {S}_{4}^{*} {S}_{4} ) .$$

Equation 4 shows how the magnitude combination of C₁ and C₂, C^{H}C, eliminates the distortions caused by phase mismatches using the identity that diagonal matrices are commutative.

$${C}^{H} C = {{ρ}^{4} ( {E}_{2 , 1}^{*} )}^{2} {( {E}_{2 , 1}^{*} )}^{2} {β}^{2} [ \begin{matrix}β & β\end{matrix} ] [ \begin{matrix}{q}_{1}^{*} & {q}_{2} \\ {q}_{2}^{*} & - {q}_{1}\end{matrix} ] [ \begin{matrix}{e}^{- i {δ}_{1}} & 0 \\ 0 & {e}^{- i {δ}_{2}}\end{matrix} ] [ \begin{matrix}{q}_{1} & {q}_{2} \\ {q}_{2}^{*} & - {q}_{1}^{*}\end{matrix} ] [ \begin{matrix}{q}_{1}^{*} & {q}_{2} \\ {q}_{2}^{*} & - {q}_{1}\end{matrix} ] [ \begin{matrix}{e}^{i {δ}_{1}} & 0 \\ 0 & {e}^{i {δ}_{2}}\end{matrix} ] [ \begin{matrix}{q}_{1} & {q}_{2} \\ {q}_{2}^{*} & - {q}_{1}^{*}\end{matrix} ] [ \begin{matrix}β \\ β\end{matrix} ] = {{ρ}^{4} ( {E}_{2 , 1}^{*} )}^{2} {( {E}_{2 , 1}^{*} )}^{2} {β}^{2} [ \begin{matrix}β & β\end{matrix} ] [ \begin{matrix}{q}_{1}^{*} & {q}_{2} \\ {q}_{2}^{*} & - {q}_{1}\end{matrix} ] [ \begin{matrix}{\vert {q}_{1} \vert}^{2} + {\vert {q}_{2} \vert}^{2} & 0 \\ 0 & {\vert {q}_{1} \vert}^{2} + {\vert {q}_{2} \vert}^{2}\end{matrix} ] [ \begin{matrix}{q}_{1} & {q}_{2} \\ {q}_{2}^{*} & - {q}_{1}^{*}\end{matrix} ] [ \begin{matrix}β \\ β\end{matrix} ] = {{ρ}^{4} ( {E}_{2 , 1}^{*} )}^{2} {( {E}_{2 , 1}^{*} )}^{2} {β}^{2} [ \begin{matrix}β & β\end{matrix} ] [ \begin{matrix}{( {\vert {q}_{1} \vert}^{2} + {\vert {q}_{2} \vert}^{2} )}^{2} & 0 \\ 0 & {( {\vert {q}_{1} \vert}^{2} + {\vert {q}_{2} \vert}^{2} )}^{2}\end{matrix} ] [ \begin{matrix}β \\ β\end{matrix} ] = 2 {{ρ}^{4} ( {E}_{2 , 1}^{*} )}^{2} {( {E}_{2 , 2}^{*} )}^{2} {( {\vert {q}_{1} \vert}^{2} + {\vert {q}_{2} \vert}^{2} )}^{2} {β}^{4} \qquad ( 4 )$$

In some implementations, for performance comparison, the ratio of two spoiled GRE images with the same TE₁ and TE₂ can be used in the proposed method. T₂* images are calculated by the direct ratio of these two GRE images which results in the same TE_{eff} as in the proposed method.

Thus, the proposed bilateral orthogonality generative acquisitions method provides whole brain T₂* images without the inhomogeneity effects of the transmit magnetic field

$$( {B}_{1}^{+} )$$

and the main static magnetic field (ΔB₀) by: acquiring a first set of two GRE acquisitions using all channels, with long echo time with and without additional transmit phase of π on the first channel or channel group; acquiring a second set of two GRE acquisitions with short echo time for each channel or channel group; combining the four acquisitions to generate two intermediate complex T₂* weighted images (as in Equation 3); and generating an MRI image optimized by removing effects based on

$${B}_{1}^{+}$$

and ΔB₀ inhomogeneity through the generation of a corrected homogeneous T₂* image by taking the square root of the summation of the intermediate images multiplied with their conjugates, respectively, and dividing it by the summation of the single-channel images multiplied with their conjugates, respectively (as in Equation 4).

In the example implementation, three healthy female volunteers (e.g., volunteers 102, 104, 106) with ages between 25-30 were recruited. Volunteer consent for the scans were acquired for each study individually, in compliance with international and national regulations for human research and data protection. For the acquisition of the data in all in vivo scans, a 7T Philips Healthcare whole body human MRI system is utilized with two transmit channels was used along with the 32 channel receive Nova Medical head coil as receive coil.

For volunteer 102 and volunteer 104, the four 3D spoiled GRE acquisitions (e.g., rows 108, 110, 112, 114) were acquired, each with voxel size of 1.5×1.5×1.5 mm, 144×144×100 acquisition matrix and 5° flip angle. TE₁/TR=20/22 ms with two averages and TE₂/TR=1.28/4.2 ms with five averages are used for the first two (rows 108, 110) and last two acquisitions (rows 112, 114). For the ratio of two spoiled GRE method described above, another spoiled GRE acquisition with the same parameters is performed as in the last two acquisitions (images of rows 112, 114). However, instead of single-channel, both channels are used as in the first acquisition (rows 108, 110). All T₂* images have the effective echo time of TE_{eff}=18.72 ms. The total scan time for the proposed method is around 30 minutes without utilization of any acceleration technique, whereas for the ratio method, the individual scan time is around 15 minutes.

For volunteer 106, four 3D spoiled GRE acquisitions were acquired using stairway acquisition for decreased scan time and higher resolution via two multi-echo GRE acquisitions further decreasing the total scan time. The first echoes from both multi-echo acquisitions correspond to the last two acquisitions in the introduced method, whereas the last two echoes correspond to the first two acquisitions in the method. All data acquisitions (e.g., rows 108, 110, 112, 114) have acquisition voxel size of 0.75×0.75×1 mm, reconstruction voxel size of 0.5×0.5×0.75 mm, 512×512×266 acquisition matrix, 5° flip angle and one average. TE₁/TR=20/35 ms and TE₂/TR=0.96/16 ms are used for first two (rows 108, 110) and last two acquisitions (rows 112, 114). However, instead of single-channel acquisitions, the last two acquisitions (rows 112, 114) are obtained in the same channel combination as the first two acquisitions (rows 108, 110) and the single-channel images are calculated as S₃=0.5 (GRE₃+GRE₄) and S₄=0.5 (GRE₃+GRE₄). Similarly, effective echo time TEₑrr=19.04 ms is obtained for all T₂* images for volunteer 106. The total scan time for the proposed method is 15 minutes, whereas for the ratio method, the total scan time is 7.5 minutes. Due to the stairway acquisitions, outer sections of the k-space are truncated.

For all volunteers (e.g., volunteers 102, 104, 106), in some implementations, complex GRE images are exported in PAR/REC format (ASCII header (PAR) plus a binary blob (REC)) from the scanner and reconstructions for both the proposed method and the ratio method are realized in MATrix LABoratory (MATLAB). Single slice display masks for images were created using the square sum of the single-channel spoiled GRE acquisitions. For volunteer 102 and volunteer 104, in some implementations, pixels with larger values than the 0.05 of the largest value in the slice are included in the mask and other pixels are discarded. On the other hand, pixels with larger values than the 0.01 of the largest value in the slice are used for volunteer 106.

For volunteer 102 and volunteer 104, noise power in the obtained T₂* images from both methods are obtained from the regions where the magnetic resonance (MR) signal is not present. In the example implementation shown, noise powers (e.g., noise variance) are calculated from 20×20 pixels at the corners of the transversal slices totaling in 1600 pixels for each slice using the variance. For volunteer 106, noise power is estimated from the transversal slices with pixels that have radial distance between 246 and 256 from the image center to reduce effect of the nuclear magnetic resonance (NMR) signal, totaling in 16064 pixels at each slice. For comparison, noise powers of the ratio method are divided by two to demonstrate the maximum possible noise power reduction that can be achieved using the same total scan time with the ratio method.

In FIG. 1, representative transversal slices of the GRE acquisitions used in the proposed method are presented for volunteer 102, volunteer 104, and volunteer 106, although any number of volunteers can be used. In the example implementation shown, row 108 shows GRE images acquired in CP mode (S₁), row 110 shows GRE images acquired with channel 1 having an additional transmit phase of π(S₂), row 112 shows GRE images of single-channel acquisition for channel 1 (S₃), and row 114 shows GRE images of single-channel acquisition for channel 2 (S₄). All images (rows 108-114) are magnitude images of spoiled GRE acquisitions and show transversal slice 50 for volunteer 102 and volunteer 104, and transversal slice 155 for volunteer 106.

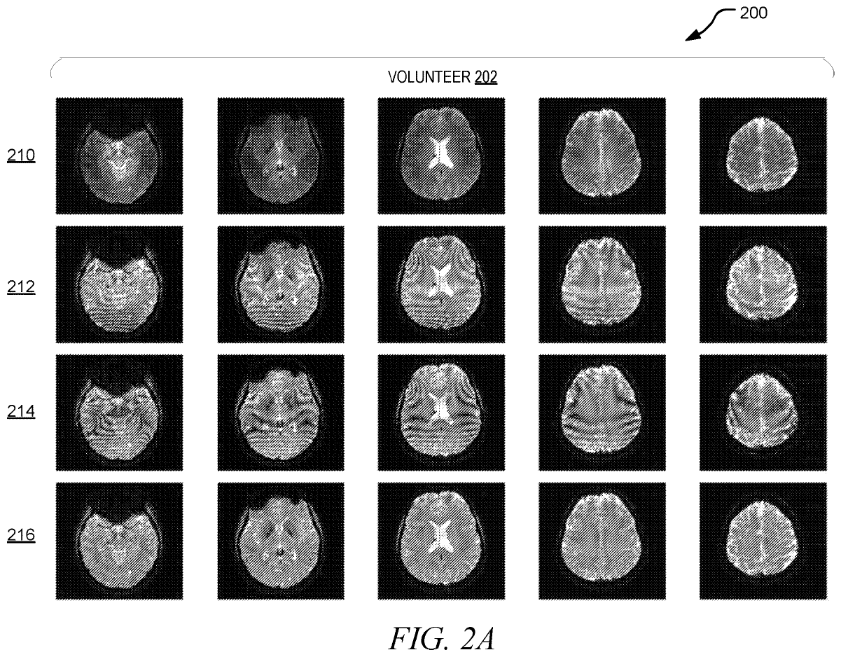

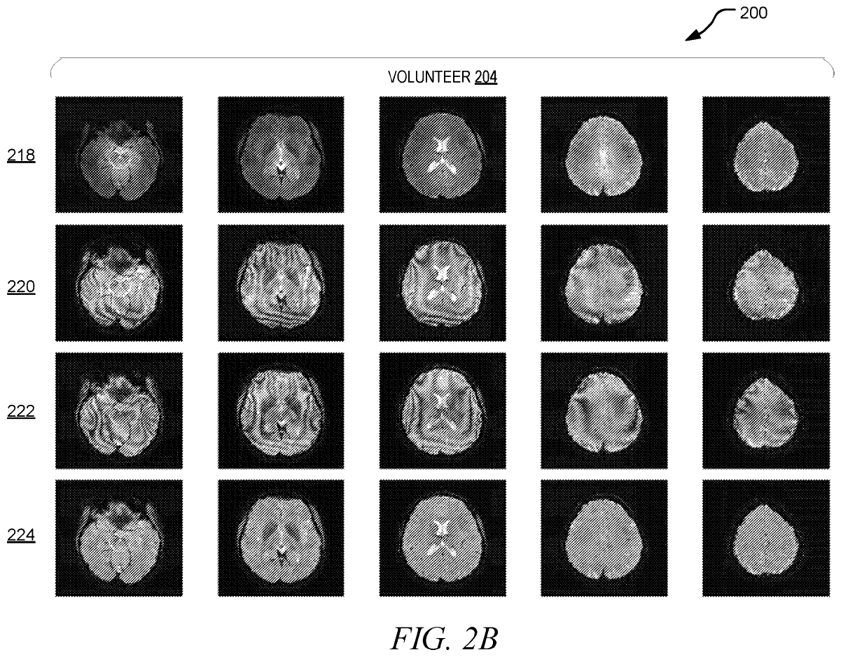

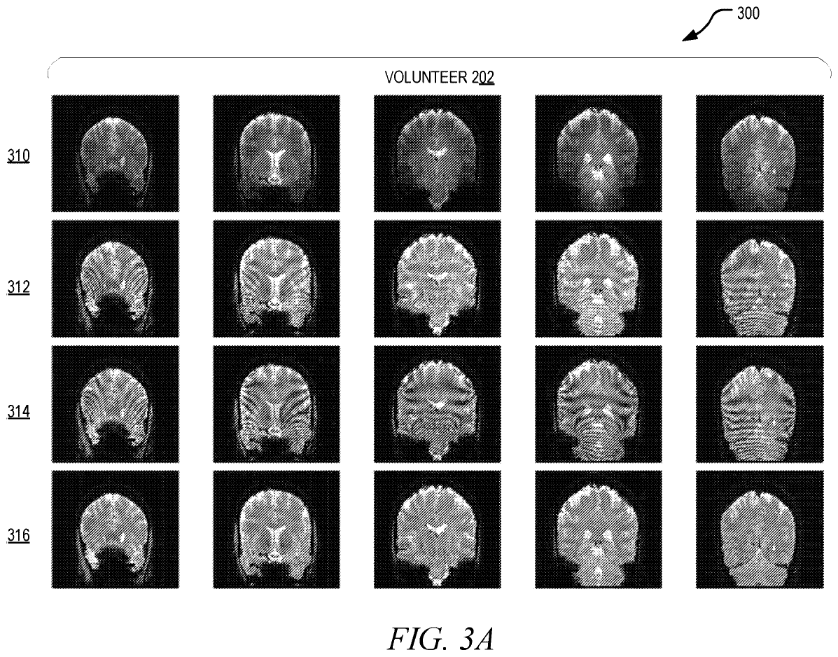

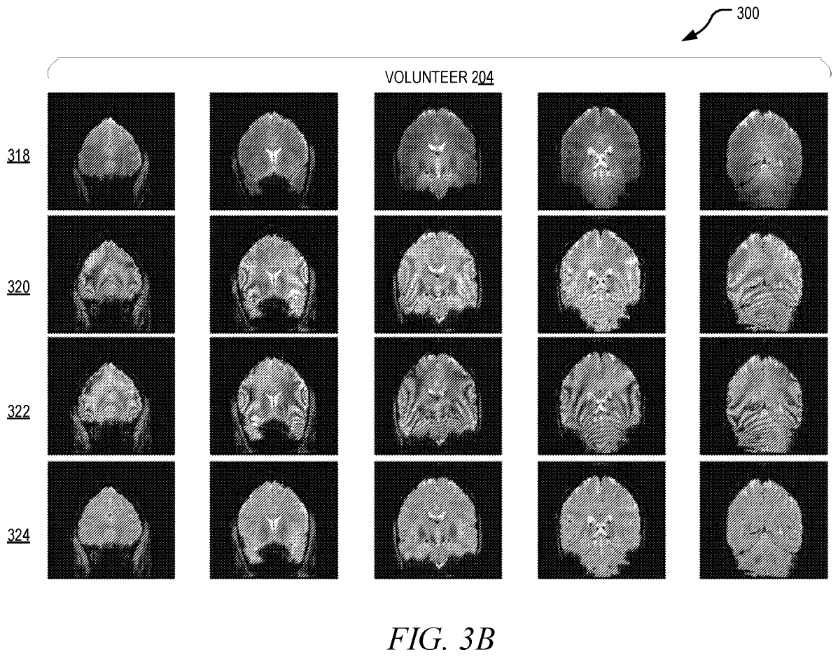

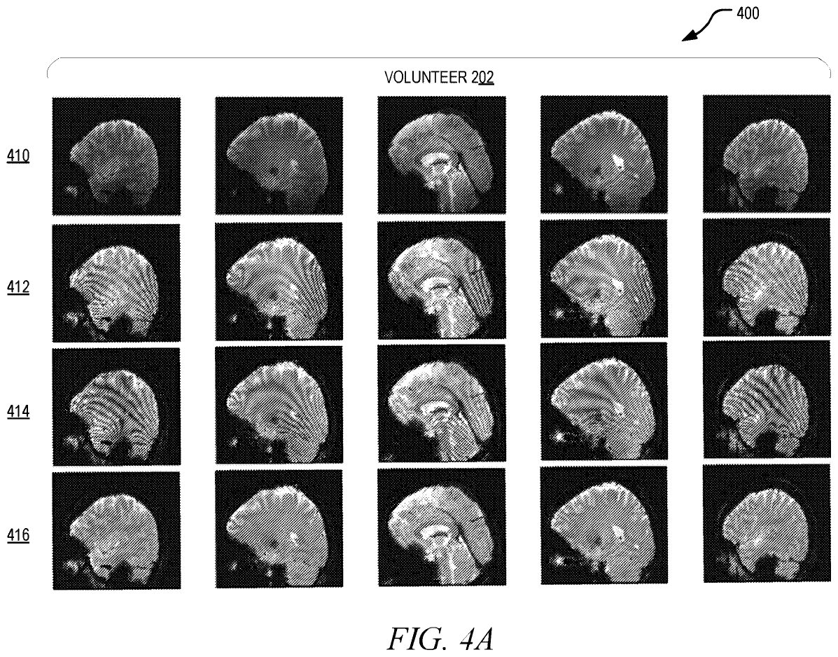

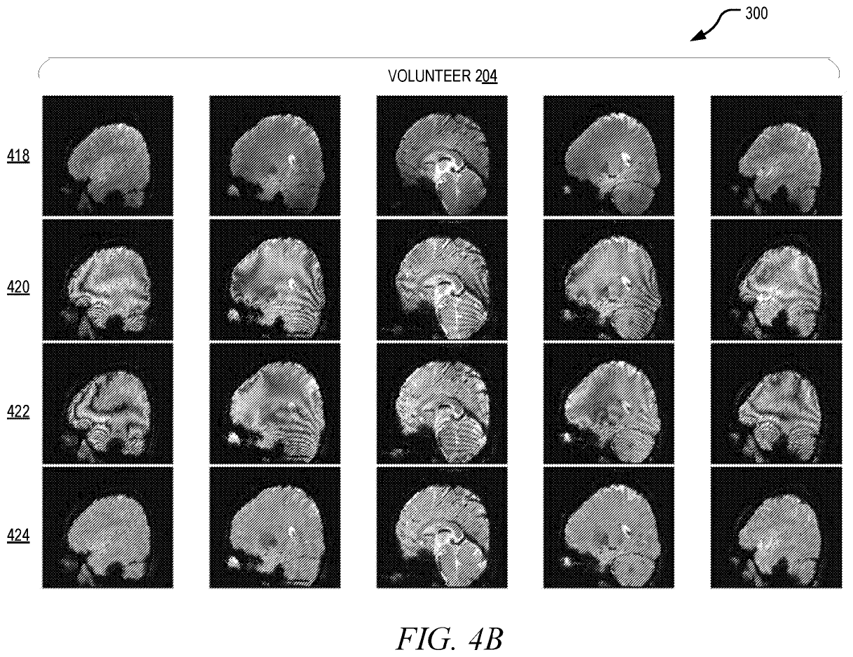

For a first volunteer (volunteer 202), FIG. 2A, FIG. 3A, and FIG. 4A show MRI slices in the transverse, coronal, and sagittal directions, respectively. Similarly, for a first volunteer (volunteer 204), FIG. 2B, FIG. 3B, and FIG. 4B show MRI slices in the transverse, coronal, and sagittal directions, respectively.

FIG. 2A illustrates representative MRI images 200 of a first volunteer (volunteer 202) in the transversal direction, and FIG. 2B illustrates representative MRI images 200 of a second volunteer (volunteer 204) in the transversal direction, in accordance with example implementations. FIGS. 2A and 2B show validation of the bilateral orthogonality method in the transversal direction: row 210 and row 218 show the CP mode image for volunteer 202 and volunteer 204, respectively; row 212 and row 220 show the magnitude of the first intermediate combined T₂* image (C₁) for volunteer 202 and volunteer 204, respectively; row 214 and row 222 show the magnitude of the second intermediate combined T₂* image (C₂) for volunteer 202 and volunteer 204, respectively; and row 216 and row 224 show the final corrected homogeneous T₂* images using the combination of C₁ and C₂ for volunteer 202 and volunteer 204, respectively. In this example implementation, all MRI images 200 are magnitude images of spoiled GRE acquisitions using a 7T dual channel TX MRI system and show transversal slices 30, 40, 50, 60 and 70 from volunteer 202 (rows 210-216) and volunteer 204 (rows 218-224).

In FIG. 2A, Row 216 for volunteer 202 shows that bilateral orthogonality methods provide whole brain T₂* images without the inhomogeneity effects of

$${B}_{1}^{+}$$

and ΔB₀, in contrast to the CP mode image in row 210 for volunteer 202. Row 212 and row 214 for volunteer 202 show that T₂* images obtained solely from C₁ and C₂ are severely affected from the phase errors in all orientations as shown in Equation 3. On the other hand, row 216 shows that the final images obtained via combination of C₁ and C₂ are not affected, which is shown in Equation 4.

In FIG. 2B, and row 224 for volunteer 204 show that bilateral orthogonality methods provide whole brain T₂* images without the inhomogeneity effects of

$${B}_{1}^{+}$$

and ΔB₀, in contrast to the CP mode image in row 218 for volunteer 204. Row 220 and row 222 for volunteer 204 show that T₂* images obtained solely from C₁ and C₂ are severely affected from the phase errors in all orientations as shown in Equation 3. On the other hand, row 224 shows that the final images obtained via combination of C₁ and C₂ are not affected, which is shown in Equation 4.

FIG. 3A illustrates representative MRI images 300 of a first volunteer (volunteer 202) in the coronal direction, and FIG. 3B illustrates representative MRI images 300 of a second volunteer (volunteer 204) in the coronal direction, in accordance with example implementations. FIGS. 3A and 3B show validation of the bilateral orthogonality method in the coronal direction: row 310 and row 318 show the CP mode image for volunteer 202 and volunteer 204, respectively; row 312 and row 320 show the magnitude of the intermediate combined T₂* image (C₁) for volunteer 202 and volunteer 204, respectively; row 314 and row 322 show the magnitude of the intermediate combined T₂* image (C₂) for volunteer 202 and volunteer 204, respectively; and row 316 and row 324 show the final corrected homogeneous T₂* images using magnitude combination of C₁ and C₂ for volunteer 202 and volunteer 204, respectively. In this example implementation, all MRI images 300 are magnitude images of spoiled GRE acquisitions using a 7T dual channel TX MRI system and show transversal slices 44, 56, 72, 86 and 100 from volunteer 202 (rows 310-316) and volunteer 204 (rows 318-324).

Row 316 for volunteer 202 in FIG. 3A, and row 324 for volunteer 204 show that the bilateral orthogonality generative acquisitions method provides whole brain T₂* images without the inhomogeneity effects of

$${B}_{1}^{+}$$

and ΔB₀, in contrast to the CP mode image in row 310 for volunteer 202 and row 318 for volunteer 204. Row 312 for volunteer 202 and row 320 for volunteer 204, and row 314 for volunteer 202 and row 322 for volunteer 204, show that T₂* images obtained solely from C₁ and C₂ are severely affected from the phase errors in all orientations as shown in Equation 3. On the other hand, row 316 and row 324 show that the final images obtained via combination of C₁ and C₂ are not affected, which is shown in Equation 4.

FIG. 4A illustrates representative MRI images 400 of a first volunteer (volunteer 202) in the sagittal direction, and FIG. 4B illustrates representative MRI images 400 of a second volunteer (volunteer 204) in the sagittal direction, in accordance with example implementations. FIGS. 4A and 4B show validation of the bilateral orthogonality generative acquisitions method in the sagittal direction: row 410 and row 418 show the CP mode image for volunteer 202 and volunteer 204, respectively; row 412 and row 420 show the magnitude of the intermediate combined T₂* image for (C₁) for volunteer 202 and volunteer 204, respectively; row 414 and row 422 show the magnitude of the intermediate combined T₂* image (C₂) for volunteer 202 and volunteer 204, respectively; and row 416 and row 424 show the final corrected homogeneous T₂* images using the combination of C₁ and C₂ for volunteer 202 and volunteer 204, respectively. In this example implementation, all MRI images 400 are magnitude images of spoiled GRE acquisitions using a 7T dual channel TX MRI system and show transversal slices 44, 56, 72, 86 and 100 from volunteer 202 (rows 410-416) and volunteer 204 (rows 418-424).

Row 416 for volunteer 202 in FIG. 4A, and row 424 for volunteer 204 show that the bilateral orthogonality generative acuisitions method provides whole brain T₂* images without the inhomogeneity effects of

$${B}_{1}^{+}$$

and ΔB₀, in contrast to the CP mode image in row 410 for volunteer 202 and row 418 for volunteer 204. Row 412 for volunteer 202 and row 420 for volunteer 204, and row 414 for volunteer 202 and row 422 for volunteer 204 show that T₂* images obtained solely from C₁ and C₂ are severely affected from the phase errors in all orientations as shown in Equation 3. On the other hand, row 416 and row 424 show that the final images obtained via combination of C₁ and C₂ are not affected, as shown in Equation 4.

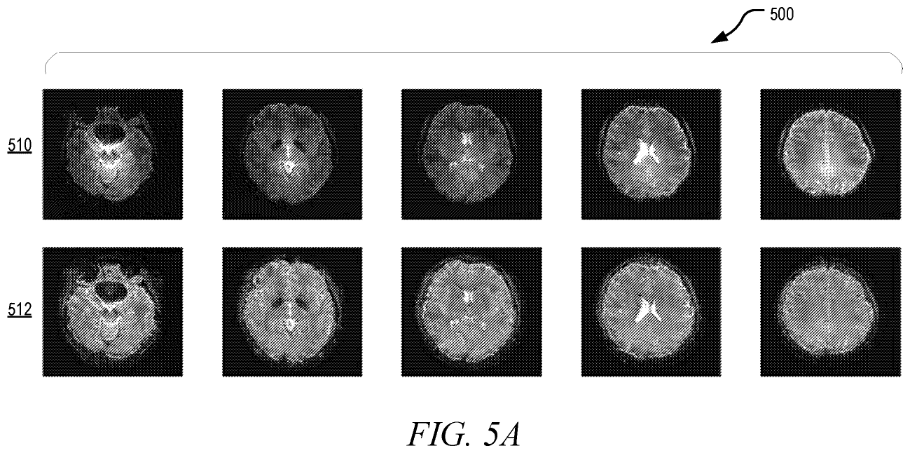

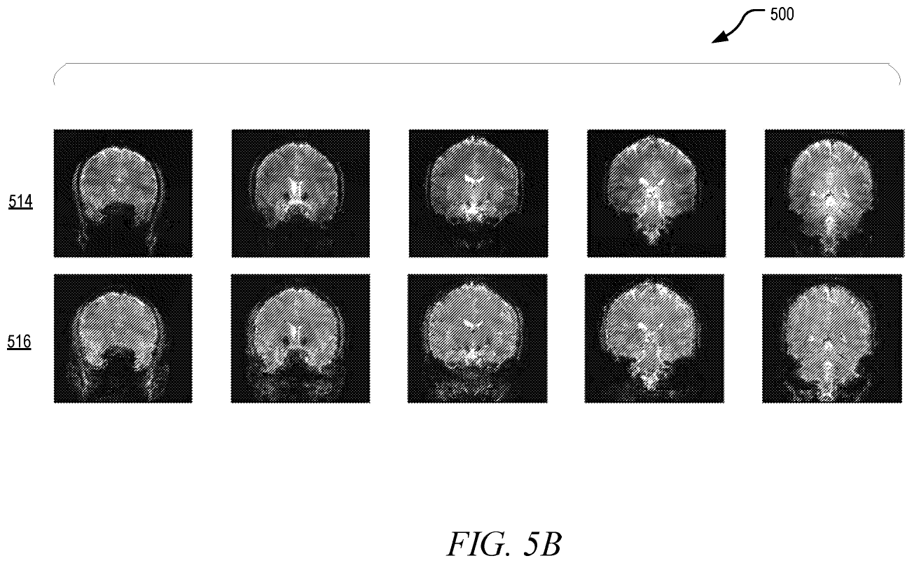

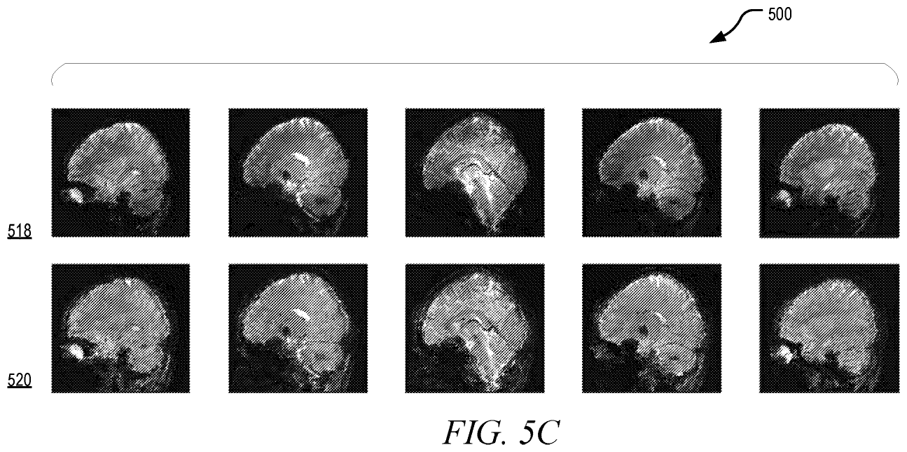

FIG. 5A, FIG. 5B, and FIG. 5C illustrate high-resolution MRI images 500 comparison for a third volunteer, in accordance with an example implementation. High-resolution images for a third volunteer are shown to illustrate comparisons between various orientations.

In FIG. 5A, row 510 shows the CP mode T₂* magnitude images in transversal orientations for slices 125, 140, 155, 160 and 175. Row 512 shows the T₂* magnitude images generated using the bilateral orthogonality generative acquisition method disclosed herein in for slices 125, 140, 155, 160 and 175 in the transversal orientations.

In FIG. 5B, row 514 shows CP mode T₂* magnitude images for slices 186, 216, 246, 276 and 306 in the coronal orientation. Row 516 shows magnitude of T₂* images obtained via the bilateral orthogonality generative acquisitions method disclosed herein for slices 186, 216, 246, 276 and 306 in the coronal orientation.

In FIG. 5B, row 518 shows CP mode T₂* magnitude images for slices 186, 216, 246, 276 and 306 in the sagittal orientation. Row 518 shows the magnitude of T₂* images obtained via the bilateral orthogonality generative acquisitions method for slices 186, 216, 246, 276 and 306 in the sagittal orientation.

In other words, FIG. 5A, FIG. 5B, and FIG. 5C contrast the CP mode images with the images obtained by bilateral orthogonality generative acquisitions method. For example, row 510, row 514, and row 518 show high resolution CP mode brain T₂* images of the volunteer in transversal, coronal and sagittal orientations, respectively. Similarly, row 512, row 516, and row 520 show high resolution brain T₂* images of the volunteer obtained via the bilateral orthogonality generative acquisitions method in transversal, coronal and sagittal orientations, which are free of the inhomogeneity effects of

$${B}_{1}^{+}$$

and ΔB₀, whereas CP mode images are affected from these inhomogeneities. The bilateral generative acquisitions orthogonality method has removed, or corrected for, the inhomogeneity effects to provide clearer and cleaner MRI images 500. Both CP mode images and the T₂* images obtained using the proposed method may, in some implementations, have small ringing artifacts at the periphery due to the stairway acquisition.

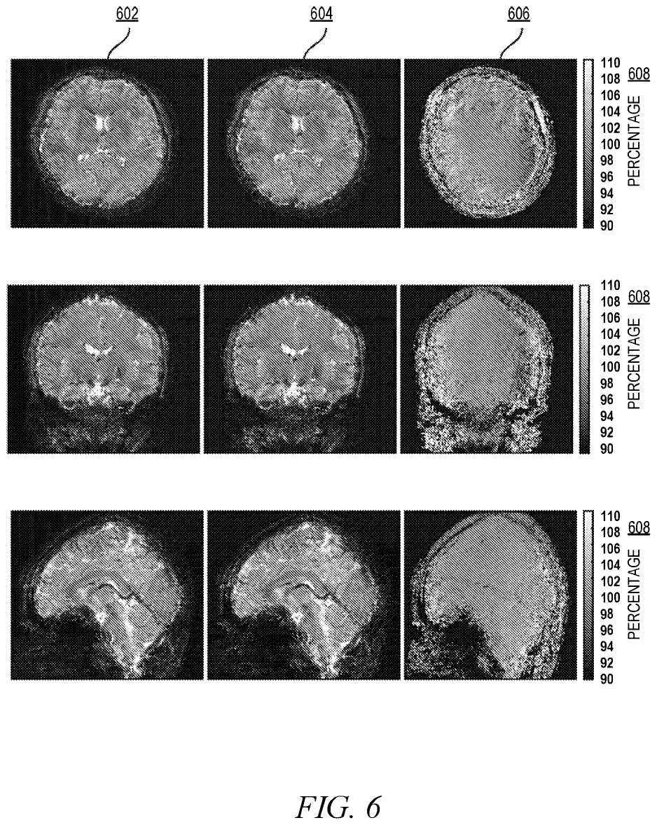

FIG. 6 illustrates a comparison of images obtained using the bilateral orthogonality method and the ratio of two GRE images, in accordance with an example implementation. Column 602 shows magnitude of T₂* images obtained via the bilateral orthogonality method, for an example volunteer in transversal (slice 155), coronal (slice 246) and sagittal (slice 246) orientations. Column 604 shows the magnitude of T₂* images obtained via the ratio of two GRE images for the example volunteer in transversal (slice 155), coronal (slice 246) and sagittal (slice 246) orientations. Column 606 shows the percentage 608 of the ratio of T₂* magnitude images in column 604 and column 602 for the volunteer.

In some implementations, column 602 of FIG. 6 demonstrates the center slices in all 3 orientations of whole brain T₂* images for the volunteer obtained via the bilateral orthogonality generative acquisitions method, whereas column 604 demonstrates images obtained via the ratio method. Finally, column 606 shows the percentage ratio of the images in column 604 and column 602, respectively. The ratio of the images indicates that in central regions with high signal intensities, both methods perform similarly. However, in the peripheral regions of the brain where the signal is low in CP mode, T₂* images obtained via the ratio method can have more variation coinciding with

$${B}_{1}^{+}$$

inhomogeneity.

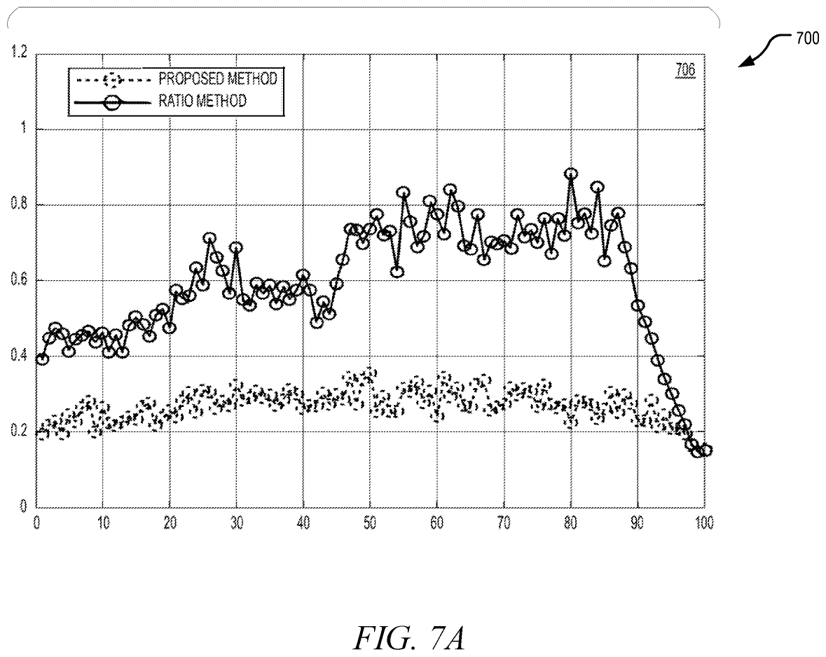

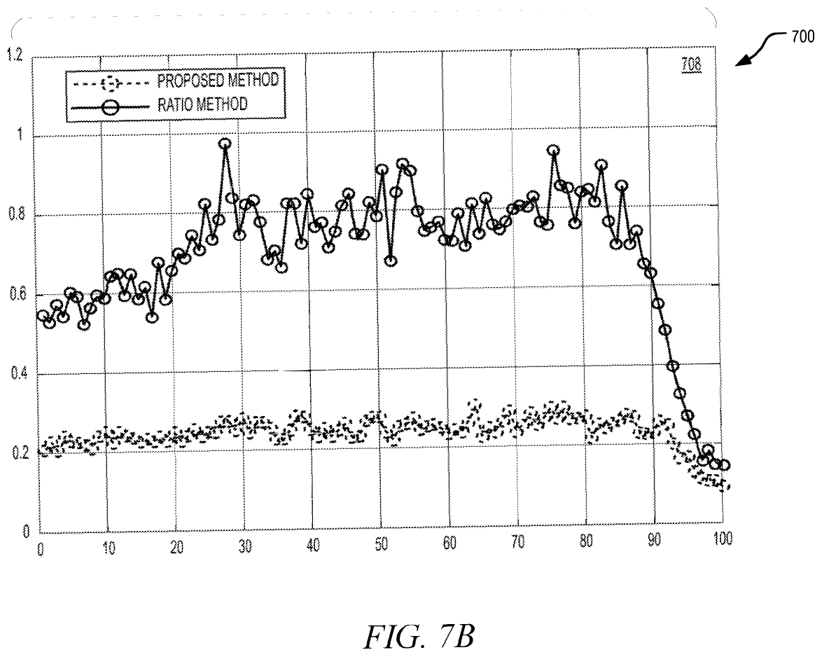

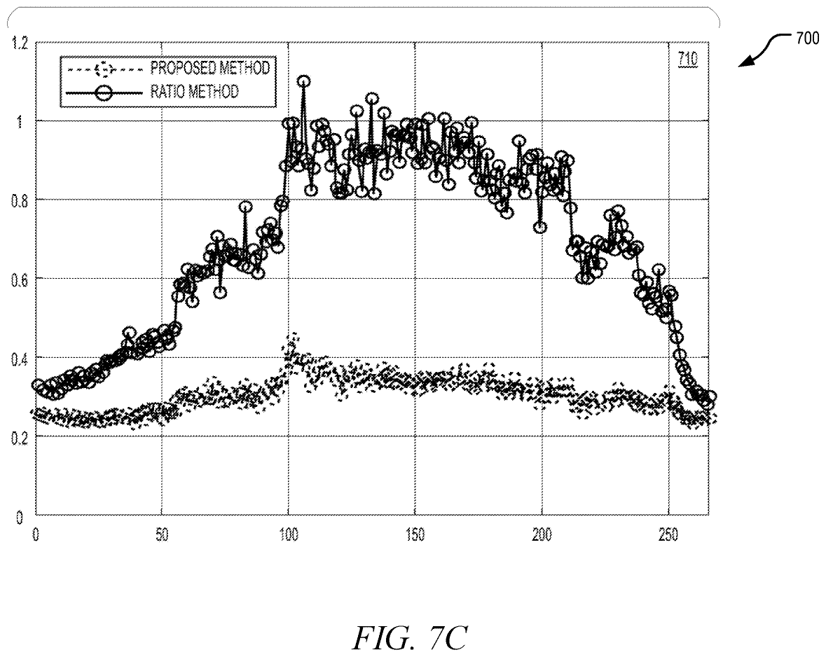

FIGS. 7A-7C show a graphical comparison of noise power for homogeneous transversal T₂* images, in accordance with example implementations. For example, to show the noise power 700 for homogeneous transversal T₂* magnitude images, the noise power is calculated from transversal slices of whole brain T₂* magnitude images obtained via the bilateral orthogonality generative acquisitions method and the ratio of two GRE images for volunteers 706, 708 and 710. In some implementations, the noise powers 700 of each transversal slice for the ratio method are adjusted for the number of averages achievable in the same total scan time duration with the bilateral orthogonality generative acquisitions method.

In some implementations, the noise powers 700 at each transversal slice for T₂* images from both methods are shown in FIGS. 7A-7C for all 3 volunteers (volunteers 706, 708, and 710), where it can be seen that in slices where NMR signal is present, the noise power for the bilateral orthogonality generative acquisitions method is significantly lower than the ratio of spoiled GRE images. Inevitable noise propagation due to the ratio for obtaining the homogeneous T₂* images is significantly less for the bilateral orthogonality method than the ratio of two GRE images for the same amount of scan time. This suggests that T₂* images via the ratio of the two GRE acquisitions result in more noise in the final T₂* images when compared to the bilateral orthogonality generative acquisitions method.

In the example implementations shown, the bilateral orthogonality generative acquisitions method results in homogeneous T₂* whole brain images using different transmit and receive coils. It is also shown that T₂* images obtained solely from C₁ and C₂ suffer from phase mismatches due to the receiving channel combination for each acquisition. Central darkening effects, such as those found on FIG. 2A-4B, can be observed in the T₂* images obtained via the bilateral orthogonality generative acquisitions method. Further scrutinization indicated that the summation of single-channel acquisition does not result in the CP mode image, suggesting that transmit power scaling for single-channel acquisitions are different from the two channel acquisitions. In order to resolve this issue, single-channel acquisitions are obtained differently for volunteer 710, which is described previously.

In some implementations, high resolution, homogeneous whole brain T₂* images can be obtained in a relatively short scan time using a stairway acquisition. Similar to FIGS. 1-3B, high resolution images in FIGS. 5A-5C indicate that the bilateral orthogonality method results in homogeneous T₂* contrast in the whole brain, where CP mode images are affected by the inhomogeneity effects of

$${B}_{1}^{+}$$

and ΔB₀. However, these high-resolution images contain some ripples that are more visible toward the periphery of the brain.

One advantage of the bilateral orthogonality generative acquisitions method is that it is less susceptible to noise enhancement and increases in noise power in the areas with low signal magnitude, which is observable in the ratio images (e.g., column 606 in FIG. 6). While T₂* images obtained using both methods coincide with each other at the central regions, there is significantly more variation in the peripheral regions. If the CP mode images corresponding to the same slices are examined, it can be seen that regions with high variations between the two methods coincide with the low B₁⁺ intensity regions in the CP mode images, thus suggesting noise enhancement in those regions. Noise enhancement in the peripheral regions can, in some implementations, also be considered an indirect effect of the B₁⁺ inhomogeneity, because these regions coincide with the low intensity regions at the CP mode images.

The noise powers for each transversal slice are provided in FIGS. 7A-7C for all 3 volunteers (volunteers 706, 708, and 710) and it is clearly demonstrated that noise propagation is more severe in the T₂* images obtained via the ratio of the two GRE images than the bilateral orthogonality generative acquisitions method. Given that noise powers of each slice of the T₂* images obtained by the ratio of two GRE images are adjusted for the averages realizable in the same scan time as the bilateral orthogonality generative acquisitions method, the bilateral orthogonality generative acquisitions method results in less noise in the final T₂* images with the same scan time. The bilateral orthogonality generative acquisitions method provides T₂* images with less overall noise for the same scan duration compared to the ratio of two GRE images.

Doubling in the required number of the acquisitions indicates that the bilateral orthogonality generative acquisitions method may work with at least double the minimum scan time required for the ratio of two GRE images for the image reconstruction. This indicates a disadvantage, in some implementations, of the bilateral orthogonality generative acquisitions method in an application where sufficiently low noise powers can be achieved via the ratio of the two GRE images. Nonetheless, this disadvantage is moot considering the aforementioned noise enhancement in the low B₁⁺ regions in the T₂* images obtained via ratio of the two GRE images, which results in inhomogeneous noise effects and hence quality degradation of the final T₂* images.

The bilateral orthogonality generative acquisitions method can be performed using existing MRI acquisition hardware because the method is performed on the MRI images are acquired using existing MRI acquisition (with different RF modes) and image reconstruction methods and then the bilateral orthogonality generative acquisitions method is performed on the MRI images to generate an artifact free/reduced MRI image. That is, the bilateral orthogonality generative acquisitions method can be performed without additional hardware or sequence design. For the GRE-version, this method can be implemented simply by the additional transmit phase of π on the first channel for the second GRE acquisition. Because no additional technical development is required for the reconstruction of the T₂* images, the bilateral orthogonality generative acquisitions method can be utilized in clinical scans conveniently without conflicting with the existing scan methods.

In the non-limiting examples illustrates in FIGS. 1-6, the MRI images S₁ and S₂ are provided by contrast generating GRE acquisitions that utilize a 20 ms echo time. However, the echo time can be adjusted for any value without the loss of generality in the method.

Therefore, the bilateral orthogonality generative acquisitions method has the benefits of being easy to implement, being robust, and providing homogeneous T₂* weighted images. As shown above, intermediate combination of the acquired signals, C₁ and C₂, results in distorted T₂* images (i.e., image with artifacts) and by combination of C₁ and C₂ distortions in the T₂* images are eliminated (i.e., image without artifacts). Finally, T₂* images are obtained by the ratio of the combination of C₁ and C₂ and single-channel acquisitions. Both low resolution and high-resolution images are free of the inhomogeneity effects, but in some implementations low resolution images obtained for volunteers 706 and 708 have slight central darkening due to single-channel scaling in the last two GRE acquisitions. This central darkening issue was resolved for volunteer 710, thus resulting in homogeneous T₂* images without the inhomogeneity effects of

$${B}_{1}^{+}$$

and ΔB₀. Compared to the simple ratio of two spoiled GRE images, the bilateral orthogonality generative acquisitions method provides less noise power in the reconstructed images for the same total scan time and more uniform noise properties throughout the whole brain.

As will be appreciated from the present disclosure, the bilateral orthogonality generative acquisitions method may be used for homogeneous T₂* images with extension to more channels. For example, in a parallel channel transmission (pTx) system, the flip angle on a single pixel via the small tip angle approximation can be calculated as

$${α}^{i} = {\sum }_{n = 1}^{N} {s}_{n}^{i} {e}^{j {θ}_{n}} [ \begin{matrix}{a}_{i 1} & … & {a}_{{iN}_{t}}\end{matrix} ] {p}_{n}$$

where pₙ denotes the pulse from channel n in vector form, sₙ, is the channel sensitivity, θₙ is the transmission phase for the optimal drive of the coil and

$${a}_{ij} = i γ {m}_{0} Δ {te}^{i γΔ {B}_{0}^{i} ( {t}_{j} - T )} {e}^{{ix}_{i} k ( {t}_{j} )} .$$

The total pulse duration is T=NₜΔt, where Δt is time step and Nₜ is the number of time steps. Additionally, k and x denote the gradient trajectory and location of the pixel, and the gyromagnetic ratio and equilibrium magnetization magnitude are respectively denoted by γ and m₀.

To generalize the bilateral orthogonality generative acquisitions method to more than two transmission channels without increasing the required number of acquisitions more than two, all available transmission channels should be combined into two groups. A reason for the disproportional increase in the number of required acquisitions is that the square orthogonal matrix suitable for the method is 2×2.

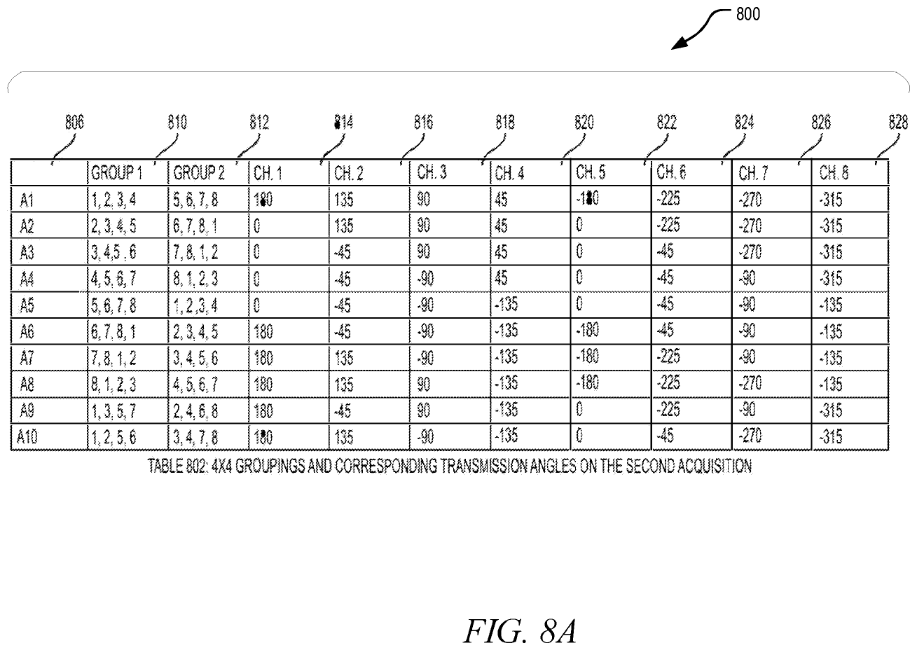

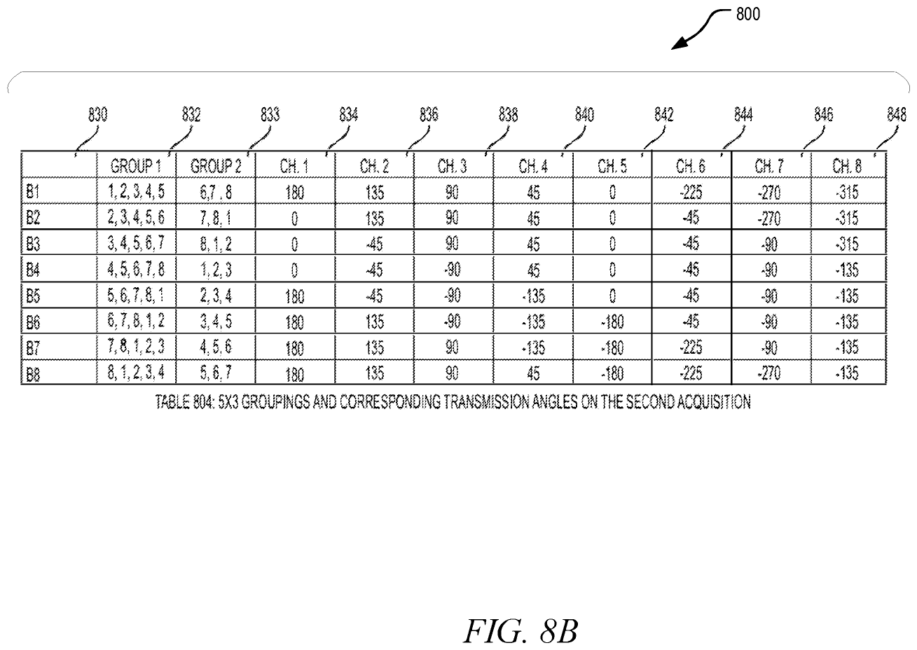

FIG. 8A illustrates 4×4 groupings and corresponding transmission angles on the second acquisition, in accordance with example implementations. FIG. 8B illustrates 5×3 groupings and corresponding transmission angles on the second acquisition, in accordance with example implementations.

In an 8 channel pTx system, the bilateral orthogonality generative acquisitions method may be utilized similar to the dual channel system without the loss of generality by defining two groups and treating the groups as two channels. In some implementations, the first acquisition is in a circularly polarized (CP mode) and during the second acquisition, an additional transmission phase of 180° is applied on all channels that belong to the first group. In FIGS. 8A and 8B, channels that belong to the first and second group for 4×4 and 5×3 groupings, respectively, and corresponding final transmission phases on the second acquisition for each channel are provided. It is worth noting that there are 70 possible 4×4 groupings and 56 possible 5×3 groupings, but only 10 of the 4×4 grouping and 8 of the 5×3 groupings have been explicitly demonstrated in FIGS. 8A and 8B.

For comparison,

$${T}_{2}^{*}$$

images obtained using the ratio of the two spoiled GRE images with different echo times corresponding to the same contrast with the bilateral orthogonality generative acquisitions method is also presented. The ratio of the final magnitude

$${T}_{2}^{*}$$

images obtained from both methods highlights the difference between the methods.

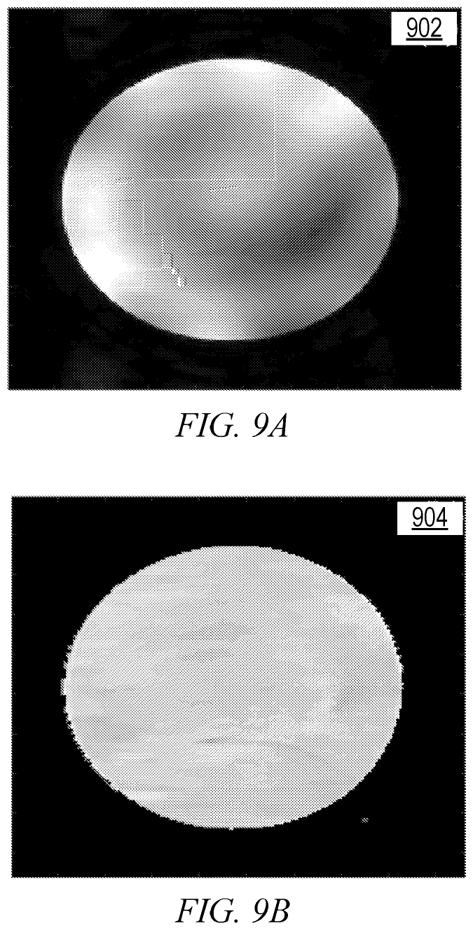

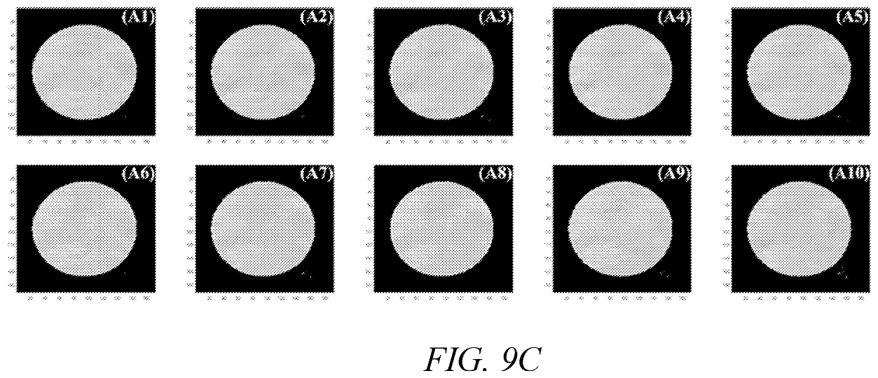

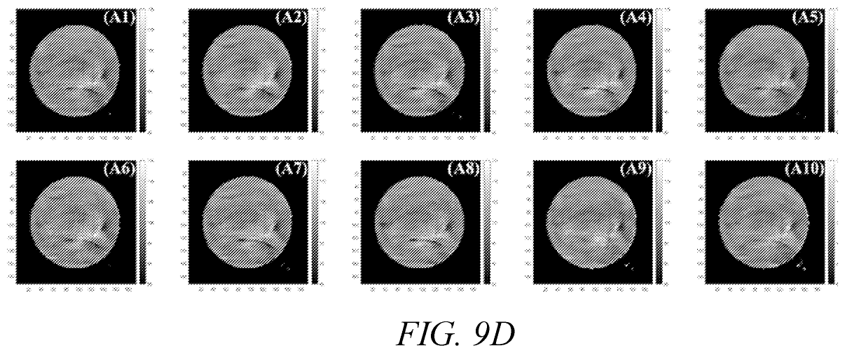

FIG. 9A illustrates an MRI image that is a circularly polarized (CP) mode

$${T}_{2}^{*}$$

image from the center transversal slice, in accordance with an example implementation. In image 902, a circularly polarized (CP) mode

$${T}_{2}^{*}$$

image from the center transversal slice with 20 ms echo time is shown, where the transmit field inhomogeneity significantly deteriorates the image quality due to inhomogeneity. Turning to FIG. 9B, the

$${T}_{2}^{*}$$

image is obtained using the ratio of two spoiled GRE images is provided in image 904, from which it can be seen that areas where the signal is low in CP mode, the image has higher values and variance compared to the other regions.

In some implementations, for each channel grouping, single 3D spoiled multi echo GRE acquisitions are acquired for uniform spherical phantom using an 8 channel inhouse-built coil. All data acquisitions have acquisition voxel size of 1.2×1.2×1.2 mm, with the same reconstruction voxel size, 192×192×192 acquisition matrix, 5° flip angle, and one average. TE₁/TE₂/TR=1.89/20/35 ms. For decreasing the scan time, a Sensitivity Encoding (SENSE) is utilized with reduction factor of 2 in both A and P. Single-channel images can be calculated as S₃=0.5 (GRE_{1,1}+GRE_{2,1}) and S₄=0.5 (GRE_{1,1}+GRE_{2,1}). GRE_{1,1} and GRE_{2,1} denote the images obtained from the first echo of the 2 multi echo spoiled GREs. The effective echo time TE_{eff}=18.11 ms is obtained for all the T₂* images. For the ratio method, the single multi echo GRE sequence with the same scan parameters can be utilized in CP mode. However, two averages are used for the ratio method to match the total scan time of the bilateral orthogonality generating acquisitions method, which in this case is 5 minutes.

The

$${T}_{2}^{*}$$

images shown in FIG. 9C are obtained generated using the bilateral orthogonality generating acquisitions method for the channel grouping combinations provided in FIG. 9A. FIG. 9D shows with the percentage ratio of

$${T}_{2}^{*}$$

images obtained via the two methods. It can be observed that

$${T}_{2}^{*}$$

images in FIG. 9C are more homogeneous than the

$${T}_{2}^{*}$$

image in FIG. 9B. Moreover, the ratio of these images shows that inhomogeneity in the low signal regions is eliminated by the bilateral orthogonality generating acquisitions methods whereas they persist in the ratio of the 2 GRE images. Similar results can be obtained showing improved homogeneity using the channel grouping combination in FIG. 9B, indicating that the number of channels in each group do not have to be the same as long as there is no common channel between channel groups.

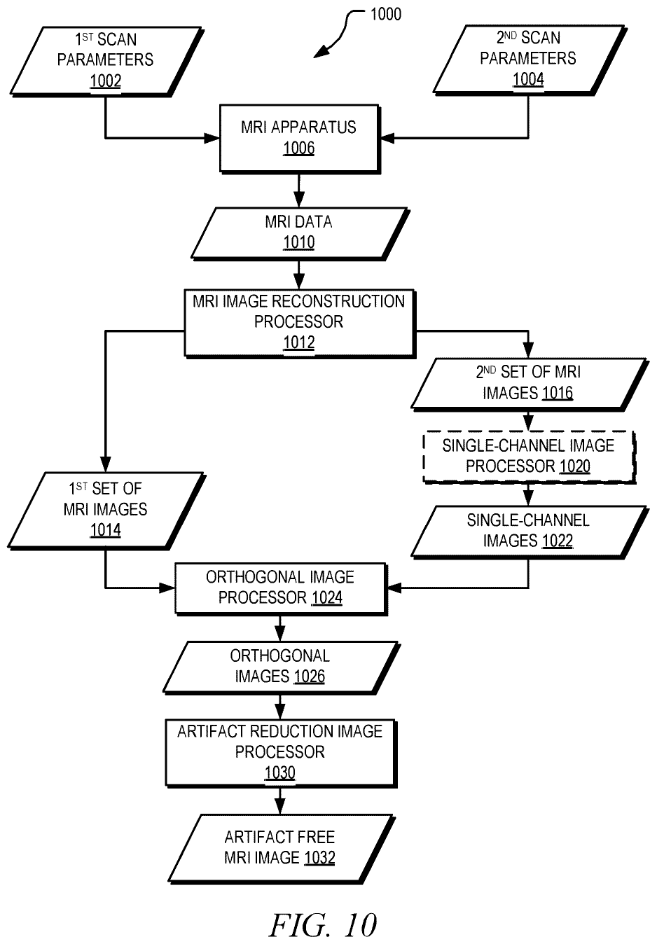

FIG. 10 illustrates a block diagram of a non-limiting example of MRI system 1000 for performing the bilateral orthogonality generating acquisitions method. MRI system 1000 is a generalization in which the system applies the bilateral orthogonality generating acquisitions method to other types of MRI pulse sequences than the GRE pulse sequence. Examples of other types of MRI pulse sequences and imaging modalities can include, e.g., spin echo sequences, gradient echo sequences, Balanced Steady State Free Precession (bSSFP) sequences, Fluid Attenuated Inversion Recovery (FLAIR) sequences, Chemical exchange saturation transfer (CEST) sequences, and Quantitative Susceptibility Mapping (QSM).

The following examples of MRI sequences are illustrative and non-limiting for the types of sequences for which the resulting MRI images can be enhanced using the bilateral orthogonality generating acquisitions method. Examples of spin echo MRI imaging sequences can include, e.g., T1 weighted spin-echo sequences, T2 weighted spin-echo sequences, and proton density weighted spin-echo sequences, fast spin-echo sequences, turbo spin-echo sequences, half-Fourier acquisition single-shot turbo spin-echo (HASTE) sequences, turbo gradient spin echo spin-echo sequences, and rapid acquisition with relaxation enhancement (RARE) sequences. Examples of gradient echo MRI imaging sequences can include, e.g., steady-state free precession (SSFP) sequences, true fast imaging with steady-state free precession (TRUFI) sequences, fast imaging with steady-state free precession (referred to as true FISP) sequences, reverse FISP sequences, dual echo steady state (DESS) sequences, fast low angle shot (FLASH) sequences, gradient recalled acquisition in the steady-state (GRASS) sequences, spoiled gradient recalled (SPGR) sequences, constructive interference in steady-state (CISS) sequences, fast imaging employing steady-state acquisition (FIESTA) sequences, multiple echo recombined gradient echo (MERGE) sequences, multi-echo data image combination (MEDIC) sequences, and single shot echo planar imaging (SS-EPI) sequences. Examples of inversion recovery (IR) sequences can include, e.g., fluid-attenuated inversion recovery (FLAIR) sequences, short tau inversion recovery (STIR) sequences, spectral attenuated inversion recovery (SPAIR) sequences, and turbo inversion recovery magnitude (TIRM) sequences.

In MRI system 1000, two sets of scan parameters (e.g., first (1^{st}) scan parameters 1002 and second (2^{nd}) scan parameters 1004) are used by an MRI apparatus 1006 for respective MRI scans to generate a total of four scans (i.e., MEI data 1010). The 1^{st} scan parameters 1002 are used in two RF modes to generate a first set of scans, which may be two or more, which are then used by the MRI image reconstruction processor 1012 to generate a first (1^{st}) set of MRI images 1014 (e.g., S₁ and S₂). The 2^{nd} scan parameters 1004 are used in two RF modes to generate a second set of scans, which may be two are more, and which are then used by the MRI image reconstruction processor 1012 to generate a second (2^{nd}) set of MRI images 1016 (e.g., S₃ and S₄).

According to certain non-limiting examples, the MRI apparatus 1006 can be a dual-channel, parallel-transmission (pTx) system. This system can be used to generate four or more data acquisitions that are to be used for the bilateral orthogonality generative acquisitions method. This is realized by using two sets of RF modes and two sets of scan parameters. For example, the four acquisitions can be viewed as a matrix with one axis representing the two RF modes and the other axis representing the two sets of scan parameters. By using two RF modes (e.g., a circular polarized (CP) mode and another RF mode having an additional phase shift, e.g., rr radians, between the channels) the above-described mathematical formulas can be used to mitigate artifacts in MRI images. For example, virtual single-channel acquisitions can be generated from one of the two sets of acquisitions (e.g., the 2^{nd} set of MRI images 1016), and the virtual single-channel acquisitions can then be used to correct the artifacts in the other of the two sets of acquisitions (e.g., the 1^{st} set of MRI images 1014, i.e., S₁ and S₂). Thus, the virtual single-channel acquisitions are used to determine the contrast of the final homogeneous image.

According to certain non-limiting examples, the first scan parameters set may be used for the contrast and the second scan parameters set may be used for channel calculation. In some other examples, the second scan parameters set may be used for contrast, and the first scan parameters set may be used for channel calculation. Scan parameter changes can be used to determine the contrast. For example, the time to echo (TE) affects the

$$\frac{{T}_{2}}{{T}_{2}^{*}}$$

weighting, whereas T₁ is affected by the repetition time (TR).

According to certain non-limiting examples, the first and second acquisitions, i.e., S₁ and S₂, are acquired using the first scan parameters set, with the MRI acquisition/image S₁ being acquired using a different RF mode than is used when acquiring the MRI acquisition/image S₂. Similarly, third and fourth acquisitions, i.e., S₃ and are acquired using the second scan parameters set, and these are also acquired using different RF modes.

Returning to FIG. 10, the second set of MRI images 1016 (S₃ and S₄) are used by the single-channel image processor 1020 to generate the single-channel images 1022. According to certain non-limiting examples, virtual single-channel acquisitions, Q₁ and Q₂, can be calculated as

$${Q}_{1} = - 0.5 ( {S}_{3} - {S}_{4} ) and {Q}_{2} = 0.5 ( {S}_{3} + {S}_{4} ) .$$

Although the single-channel images 1022 can be calculated from a single muti-channel MRI acquisition and are not actual single-channel acquisitions, they can nevertheless be referred to as virtual single-channel acquisitions.

Alternatively, the 2^{nd} set of MRI images 1016 (S₃ and S₄) can be directly acquired as single-channel acquisitions, in which case the single-channel image processor 1020 can be omitted (the dashed line around the single-channel image processor 1020 is used to indicate that it can be omitted) because single-channel acquisitions, Q₁ and Q₂, are simply given by

$${Q}_{1} = {S}_{3} and {Q}_{2} = {S}_{4} .$$

To reduce the acquisition time, it can be preferable to acquire the 2^{nd} set of MRI images 1016 (S₃ and S₄) in a single MRI acquisition and then derive the virtual single-channel acquisitions, Q₁ and Q₂, as discussed above, rather than performing two MRI scans to directly acquire the single-channel acquisitions, i.e., Q₁=S₃ and Q₂=S₄.

Then the single-channel images 1022 and the 1^{st} set of MRI images 1014 can be used by the orthogonal image processor 1024 to generate the orthogonal images 1026, C₁ and C₂. According to certain non-limiting examples, the orthogonal image processor 1024 combines the four signals as discussed above for the GRE case. That is, C₁ and C₂ can be defined as

$${C}_{1} = {Q}_{1}^{*} {S}_{1} + {Q}_{2} {S}_{2}^{*} and {C}_{2} = {Q}_{2}^{*} {S}_{1} - {Q}_{1} {S}_{2}^{*} .$$

The images C₁ and C₂ are referred to as orthogonal images 1026 because the above calculation ensures that these images satisfy the mathematical relation of the bilateral orthogonality generative acquisitions method.

Then the orthogonal images 1026 can be used by the orthogonal image processor 1024 to generate an artifact-free MRI image 1032. According to certain non-limiting examples, the final image I (e.g., the artifact-free MRI image 1032) is calculated as

$$I = \frac{\sqrt{0.5 {C}^{H} C}}{{Q}_{3}^{*} {Q}_{3} + {Q}_{4}^{*} {Q}_{4}} ,$$

which is the homogeneous image with the desired contrast. Although the bilateral orthogonality generative acquisitions (BOGA) method is illustrated above using the non-limiting example of complex images, the method generalizes to magnitude images (e.g., images in which the voxels are real numbers—not imaginary numbers).

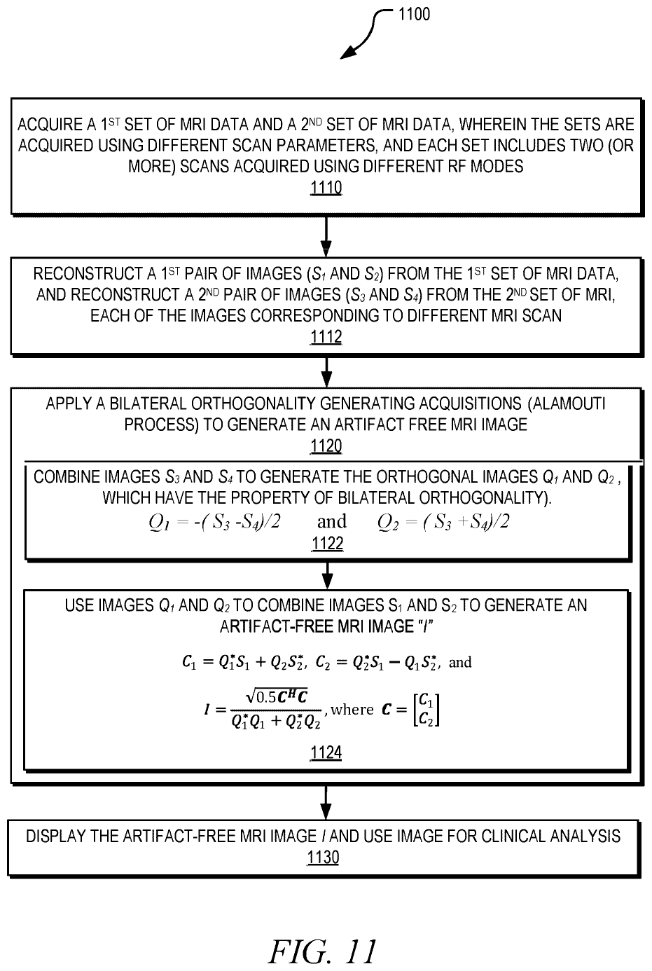

FIG. 11 illustrates a first example of method 1100 for generally using the bilateral orthogonality generating acquisitions method for different types of MRI pulse sequences and imaging modalities. Although the example routine depicts a particular sequence of operations, the sequence may be altered without departing from the scope of the present disclosure. For example, some of the operations depicted may be performed in parallel or in a different sequence that does not materially affect the function of the routine. In other examples, different components of an example device or system that implements the routine may perform functions at substantially the same time or in a specific sequence.

According to some examples, in step 1110, the method includes acquiring a 1^{st} set of MRI data and a 2^{nd} set of MRI data. As discussed above, these sets are acquired using different scan parameters, and each set includes two (or more) scans acquired using different RF modes.

According to some examples, in step 1112, the method includes reconstructing a 1^{st} pair of images (S₁ and S₂) from the 1^{st} set of MRI data. Further, step 1112 includes reconstructing a 2^{nd} pair of images (S₃ and S₄) from the 2^{nd} set of MRI. Each of these four images corresponds to a different MRI scan that was acquired in step 1110.

According to some examples, in process 1120, the method includes applying a bilateral orthogonality generating acquisition method to generate an artifact-reduced MRI image. The bilateral orthogonality generating acquisition method uses the space-time diversity provided by the MRI system including multiple receive antennas and performing multiple scans to mitigate undesired signals/artifacts from the final MRI image. The MRI images from different scans and different RF receivers are combined to generate an orthogonality between virtual signal channel acquisitions, which can then be combined with other MRI images to mitigate undesired signals/artifacts from the final MRI image. This process builds on the space time diversity method for wireless communications, which is described in Alamouti SM. A simple transmit diversity technique for wireless communications. IEEE Journal on Selected Areas in Communications. 1998; 16(8):1451-1458. doi:10.1109/49.730453 and further described in Goldsmith A. Wireless Communications, Chapter 7, Cambridge University Press; 2013, both of which is incorporated herein by reference in its entirety. Here, space time diversity is leveraged by using two receive RF coils/antennas when combining one set of images to generate the virtual signal channel acquisitions.

Process 1120 includes steps 1122 and 1124. In step 1112, process 1120 includes combining images S₃ and S₄ to generate the virtual single-channel acquisitions Q₁ and Q₂, which satisfy the mathematical relation of the bilateral orthogonality. The virtual single-channel acquisitions, Q₁ and Q₂, can be calculated as

$${Q}_{1} = - 0.5 ( {S}_{3} - {S}_{4} ) and {Q}_{1} = 0.5 ( {S}_{3} + {S}_{4} ) .$$

In step 1124, process 1120 includes using images Q₁ and Q₂, to combine images S₁ and S₂ to generate an artifact-free MRI image “I.” The artifact-free MRI image can be calculated as

$$I = \frac{\sqrt{0.5 {C}^{H} C}}{{Q}_{3}^{*} {S}_{3} + {Q}_{4}^{*} {S}_{4}} ,$$

wherein C, C₁ and C₂ are defined as

$${C}_{1} = {Q}_{1}^{*} {S}_{1} + {Q}_{2} {S}_{2}^{*} ; {C}_{2} = {Q}_{2}^{*} {S}_{1} - {Q}_{1} {S}_{2}^{*} ; and C = [ \begin{matrix}{C}_{1} \\ {C}_{2}\end{matrix} ] .$$

According to some examples, in step 1130, the method includes displaying the artifact-free MRI image “I” and using this image for clinical analysis.

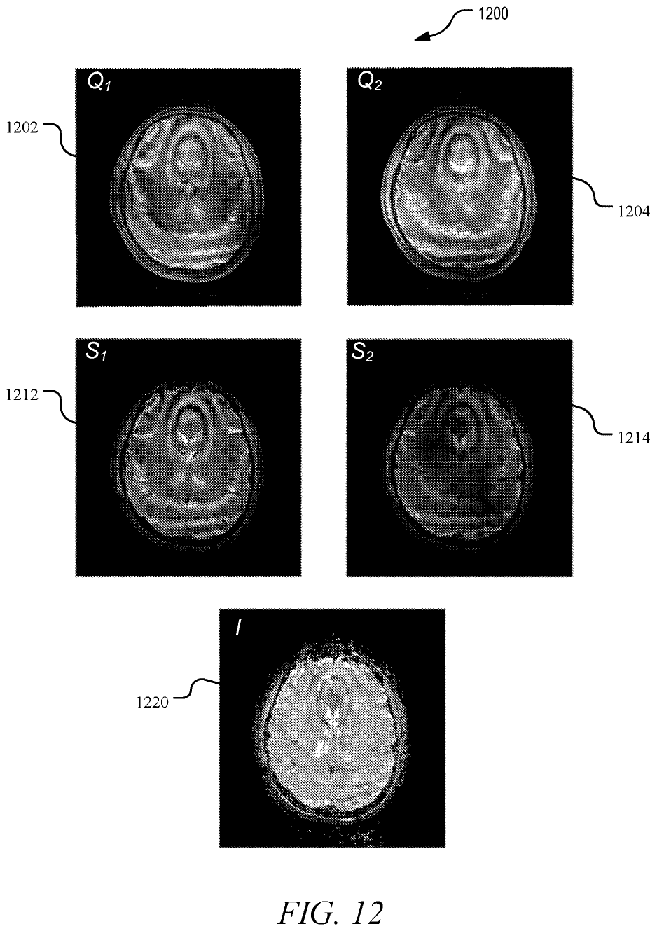

As discussed above, the bilateral orthogonality generative acquisitions method can be used with different types of MRI imaging. FIGS. 12-15 illustrate four non-limiting examples of the bilateral orthogonality generative acquisitions (BOGA) method being applied in four different MRI imaging contests with four different MRI imaging pulse sequences.

FIG. 12 illustrates the non-limiting example of using the BOGA method for balanced steady state free precession (bSSFP) MRI imaging. In FIG. 12, a set of images 1200 is shown, including a first set of images (i.e., a slice for a first image S₁ 1212 and a second image S₂ 1214) and a set of virtual single-channel acquisitions (i.e., Q₁1202 and Q₂ 1204). These four images are combined as discussed above to form the final image 11220.

For the images shown in FIG. 12, the bSSFP acquisitions were acquired each with voxel size of 1×1×1 mm to generate a 3D image in which the voxels make up a 256×256×192 acquisition matrix. Further, the images were acquired using a turbo field echo (TFE) factor of 3800 and using a compressed sensitive encoding (SENSE) factor of 9, with a 5⁰ flip angle. In each set of acquisitions, the first acquisition is acquired using an echo-time-to-repetition-time ratio of TE1/TR=12.3/25 ms, and the second acquisition is acquired using an echo-time-to-repetition-time ratio of TE2/TR=2.3/25 ms. The final image 11220 is a T₂ contrast image.

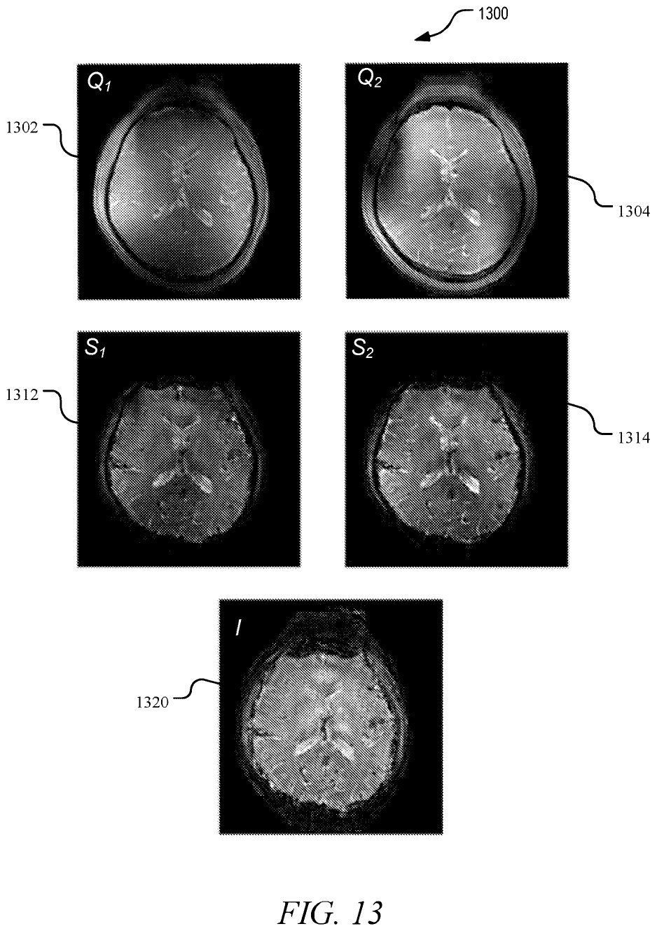

FIG. 13 illustrates the non-limiting example of using the BOGA method for multi-echo GRE MRI imaging. In FIG. 13, a set of images 1300 is shown, including a first set of images (i.e., a slice for a first image S₁ 1312 and a second image S₂ 1314) and a set of virtual single-channel acquisitions (i.e., Q₁1302 and Q₂ 1304). These four images are combined as discussed above to form the final image 11320.

For the images shown in FIG. 13, the multi echo GRE acquisitions were acquired each with voxel size of 0.75×0.75×0.75 mm to generate a 3D image in which the voxels make up a 288×288×200 acquisition matrix. Further, the images were acquired using a TFE factor of 120 and using a compressed sensitive encoding (SENSE) factor of 7, with a 50° flip angle. In each set of acquisitions, the first acquisition is acquired using an echo-time-to-repetition-time ratio of TE1/TR=2.03/22.56 ms, and the second acquisition is acquired using an echo-time-to-repetition-time ratio of TE2/TR=20/22.56 ms. The final image 11220 is a

$${T}_{2}^{*}$$

contrast image.

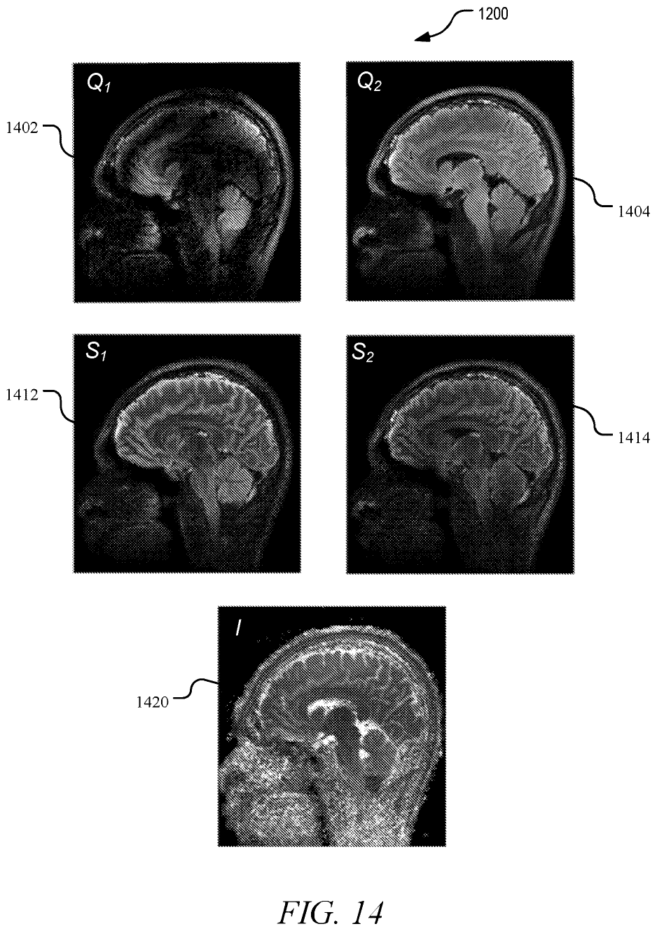

FIG. 14 illustrates the non-limiting example of using the BOGA method for fluid attenuated inversion recovery (FLAIR) MRI imaging. In FIG. 14, a set of images 1200 is shown, including a first set of images (i.e., a slice for a first image S₁ 1412 and a second image S₂ 1414) and a set of virtual single-channel acquisitions (i.e., Q₁1402 and Q₂ 1404). These four images are combined as discussed above to form the final image 11420.

For the images shown in FIG. 14, the multi echo GRE acquisitions were acquired each with voxel size of 1×1×1 mm to generate a 3D image in which the voxels make up a 224×224×200 acquisition matrix. Further, the images were acquired using a turbo spin echo (TSE) factor of 150, an inversion time a 400 ms, and a flip angle of 90°. In each set of acquisitions, the first acquisition is acquired using an echo-time-to-repetition-time ratio of TE1/TR=520/8000 ms, and the second acquisition is acquired using an echo-time-to-repetition-time ratio of TE2/TR=260/8000 ms. The final image 11220 is a T₂ contrast image.

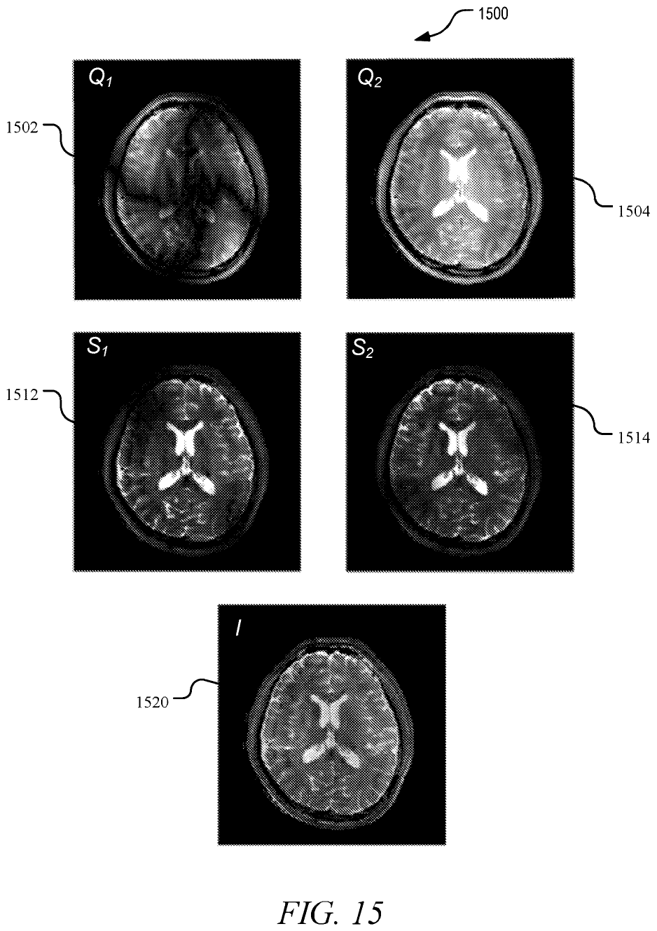

FIG. 15 illustrates the non-limiting example of using the BOGA method for Spin Echo (SE) MRI imaging. In FIG. 15, a set of images 1500 is shown, including a first set of images (i.e., a slice for a first image S₁ 1512 and a second image S₂ 1514) and a set of virtual single-channel acquisitions (i.e., Q₁1502 and Q₂ 1504). These four images are combined as discussed above to form the final image 11520.

For the images shown in FIG. 15, the SE acquisitions were acquired each with voxel size of 1×1×1 mm to generate a 3D image in which the voxels make up a 224×224×200 acquisition matrix. Further, the images were acquired using a turbo spin echo (TSE) factor of 8 and a flip angle of 90°. In each set of acquisitions, the first acquisition is acquired using an echo-time-to-repetition-time ratio of TE1/TR=73/28000 ms, and the second acquisition is acquired using an echo-time-to-repetition-time ratio of TE2/TR=23/28000 ms. The final image I 1220 is a T₂ contrast image.

As another example of applying the BOGA method to another modality of MRI imaging. The BOGA method can be used for generating MRI images based on Dixon encoding two GRE images with a phase difference between water and fat. For example,

$${R}_{2}^{*} ( {T}_{2}^{*} )$$

contrast can be used for diagnostics in liver and kidney using multi-echo gradient echo (GRE) acquisitions. Further, Dixon imaging along with the

$${R}_{2}^{*} ( {T}_{2}^{*} )$$

relaxometry can be used for liver imaging.

In this example, the Bilateral Orthogonality Generative Acquisitions (BOGA) method is illustrated using the non-limiting example of acquiring the four scans (i.e., two sets of scans) using a 3T scanner with a dual channel transmit body coil and adapted for simultaneous

$${R}_{2}^{*} ( {T}_{2}^{*} )$$

relaxometry and Dixon imaging in order to obtain homogeneous images without the central brightening effects due to the transmit field,

$$( {B}_{1}^{+} ) ,$$

inhomogeneity.

As discussed above, four MRI scans are performed. In this example, the first set of two scans/images are acquired as circularly polarized (CP) mode image

$${S}_{1} = ρ {E}_{2 , 1}^{*} ( {q}_{1} + {q}_{2} ) β ,$$

adding a transmit phase of 180° to the first transmit channel to achieve an excitation pattern

$${S}_{2} = ρ {E}_{2 , 1}^{*} ( - {q}_{1} + {q}_{2} ) β .$$

The other set of two scans/images are given by

$${S}_{3 , 4} = ρ {E}_{2 , 2}^{*} {q}_{1 , 2} β .$$

For application of the Dixon imaging with the Bilateral Orthogonality Generative Acquisitions method, phase information due to the off-resonance effects has to be calculated accurately. To achieve this, intermediate complex images C and D, are utilized. which is calculated as,

More particularly, the vector C can be calculated as.

$$C = [ \begin{matrix}{C}_{1} \\ {C}_{2}\end{matrix} ] = [ \begin{matrix}{Q}_{1}^{*} & {Q}_{2} \\ {Q}_{2}^{*} & - {Q}_{1}\end{matrix} ] [ \begin{matrix}{S}_{1} \\ {S}_{2}^{*}\end{matrix} ] = [ \begin{matrix}{q}_{1}^{*} β & {q}_{2} β \\ {q}_{2}^{*} β & - {q}_{1} β\end{matrix} ] [ \begin{matrix}{e}^{i γ} & 0 \\ 0 & {e}^{- i γ}\end{matrix} ] [ \begin{matrix}{q}_{1} & {q}_{2} \\ {q}_{2}^{*} & - {q}_{1}^{*}\end{matrix} ] [ \begin{matrix}β \\ β\end{matrix} ] = {ρ}^{2} {E}_{2 , 1}^{*} {E}_{2 , 2}^{*} {β}^{2} [ \begin{matrix}{\vert {q}_{1} \vert}^{2} {e}^{i γ} + {\vert {q}_{2} \vert}^{2} {e}^{- i γ} + ( {e}^{i γ} - {e}^{- i γ} ) {q}_{1}^{*} {q}_{2} \\ {\vert {q}_{1} \vert}^{2} {e}^{- i γ} + {\vert {q}_{2} \vert}^{2} {e}^{i γ} + ( {e}^{i γ} - {e}^{- i γ} ) {q}_{1} {q}_{2}^{*}\end{matrix} ] .$$

Similarly, a complimentary set of intermediary images can also be written as follows.

$$D = [ \begin{matrix}{D}_{1} \\ {D}_{2}\end{matrix} ] = [ \begin{matrix}{Q}_{1}^{*} & - {Q}_{2} \\ {Q}_{2}^{*} & {Q}_{1}\end{matrix} ] [ \begin{matrix}{S}_{1} \\ {S}_{2}^{*}\end{matrix} ] = [ \begin{matrix}{q}_{1}^{*} β & - {q}_{2} β \\ {q}_{2}^{*} β & {q}_{1} β\end{matrix} ] [ \begin{matrix}{e}^{i γ} & 0 \\ 0 & {e}^{- i γ}\end{matrix} ] [ \begin{matrix}{q}_{1} & {q}_{2} \\ {q}_{2}^{*} & - {q}_{1}^{*}\end{matrix} ] [ \begin{matrix}β \\ β\end{matrix} ] = {ρ}^{2} {E}_{2 , 1}^{*} {E}_{2 , 2}^{*} {β}^{2} [ \begin{matrix}{\vert {q}_{1} \vert}^{2} {e}^{i γ} - {\vert {q}_{2} \vert}^{2} {e}^{- i γ} + ( {e}^{i γ} + {e}^{- i γ} ) {q}_{1}^{*} {q}_{2} \\ - {\vert {q}_{1} \vert}^{2} {e}^{- i γ} + {\vert {q}_{2} \vert}^{2} {e}^{i γ} + ( {e}^{i γ} + {e}^{- i γ} ) {q}_{1} {q}_{2}^{*}\end{matrix} ] ,$$

where γ=2πΔBᵢΔTE is the phase accumulated between echoes, ΔB₀ denotes the main field inhomogeneity, ΔTE denotes the difference between echo times, q denotes the channel effects, β is the flip angle and

$${E}_{2}^{*}$$

is the

$${T}_{2}^{*}$$

decay.

The final MRI image I is calculated using these intermediate images C and D by calculating

$$I = F / E ,$$

$$wherein E = ( {S}_{3}^{*} {S}_{3} + {S}_{4}^{*} {S}_{4} ) , \\ and F = 0.25 ( {C}_{1} + {D}_{1} + {C}_{2} + {D}_{2} + {( {C}_{1} - {D}_{1} + {C}_{2} - {D}_{2} )}^{*} ) .$$

Although, the final combination to generate the final image is different in this case compared to the previous implementations of BOGA method, this example still uses the same ideas of using the images C=[C₁ C₂]^{T}, in a combination to generate the final image I.

For Dixon imaging, a normalized complex

$$( {F}_{2}^{N} )$$

combined image, represents the phase encoding acquired to distinguish water and fat due to their chemical shift difference. Complex water and fat masks, denoted as WM and FM respectively, are then calculated as

$$WM = 0.5 ( 1 + {F}_{2}^{N} ) and FM = 0.5 ( 1 - {F}_{2}^{N} ) .$$

Since fat and water content does not change between echoes and same masks can be used for every echo for obtaining water only and fat only images and

$${R}_{2}^{*}$$

images.

By applying BOGA method to every echo except the first one and the logarithmic identities,

$${R}_{2}^{*}$$

is estimated as follows using N echoes. Mₖ denotes the mask for water only and fat only images, for the joint image Mₖ is 1. K=0.5N(N−1)ΔTE is the total duration for the

$${R}_{2}^{*}$$

decay from all echoes.

$${R}_{2 , s}^{*} = \frac{1}{K} ( {\sum }_{i = 2}^{12} - ( i - 1 ) ( ln ( \vert {M}_{k} {F}_{i} \vert ) - ln ( {\vert {M}_{k} \vert}^{2} E ) ) ) .$$

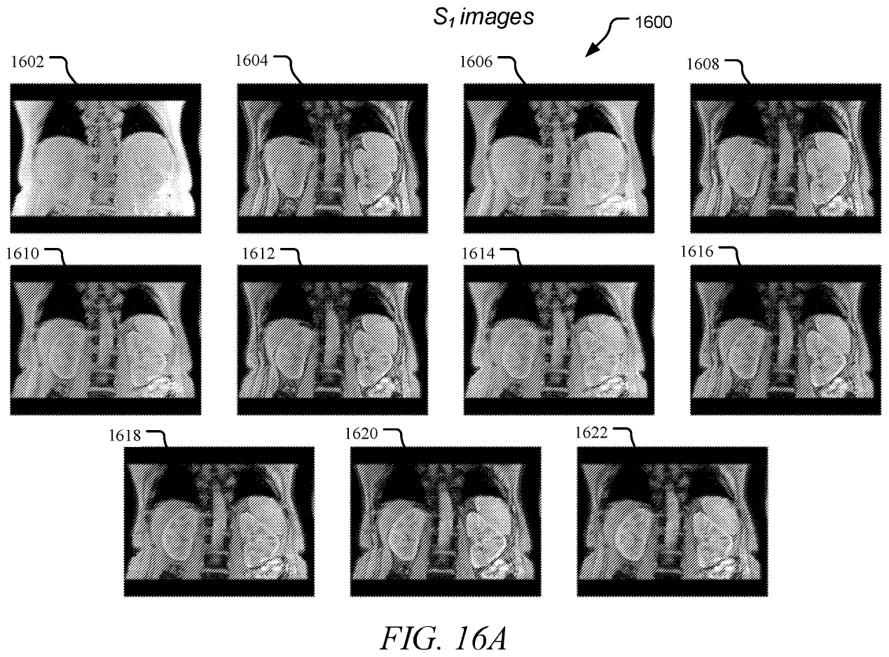

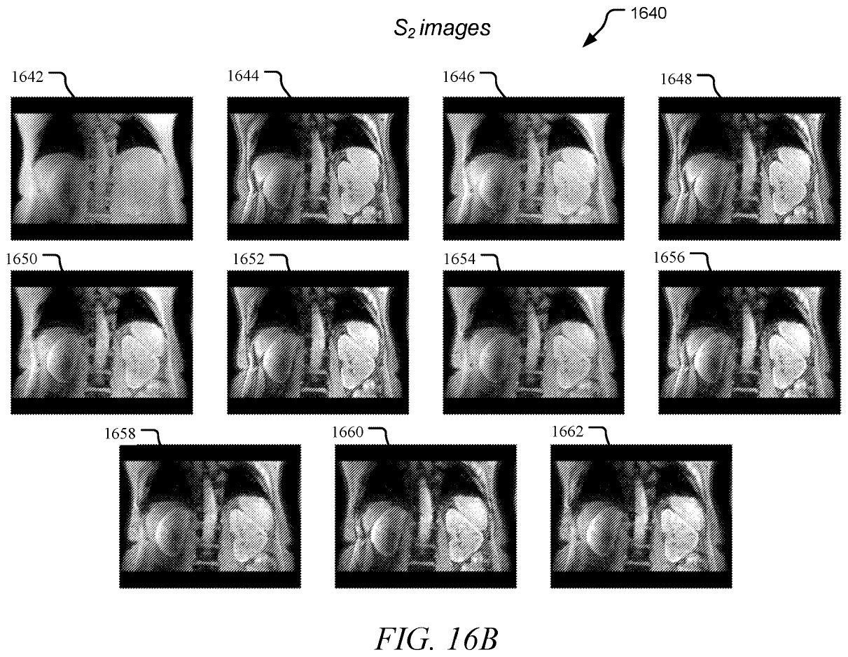

FIGS. 16A and 16B respectively illustrate a sequence 1600 of eleven S₁ images (i.e., image 1602, image 1604, image 1606, image 1608, image 1610, image 1612, image 1614, image 1616, image 1618, image 1620, and image 1622) and a sequence 1640 of eleven S₂ images (i.e., image 1642, image 1644, image 1646, image 1648, image 1650, image 1652, image 1654, image 1656, image 1658, image 1660, and image 1662) that were acquired in a demonstration of using the BOGA method with Dixon imaging. These images represent the magnitude of the center slice of the echoes 2 to 12 of input images S₁ and S₂ for the Bilateral Orthogonality Generative Acquisitions method for obtaining eleven homogeneous

$${T}_{2}^{*}$$

weighted images of kidneys with TE 2.31 ms to 14.41 ms, that are used in

$${R}_{2}^{*}$$

estimation. These sequences of images are eleven echoes of the GRE acquisitions that are used as the S₁ and S₂ images for the BOGA method.

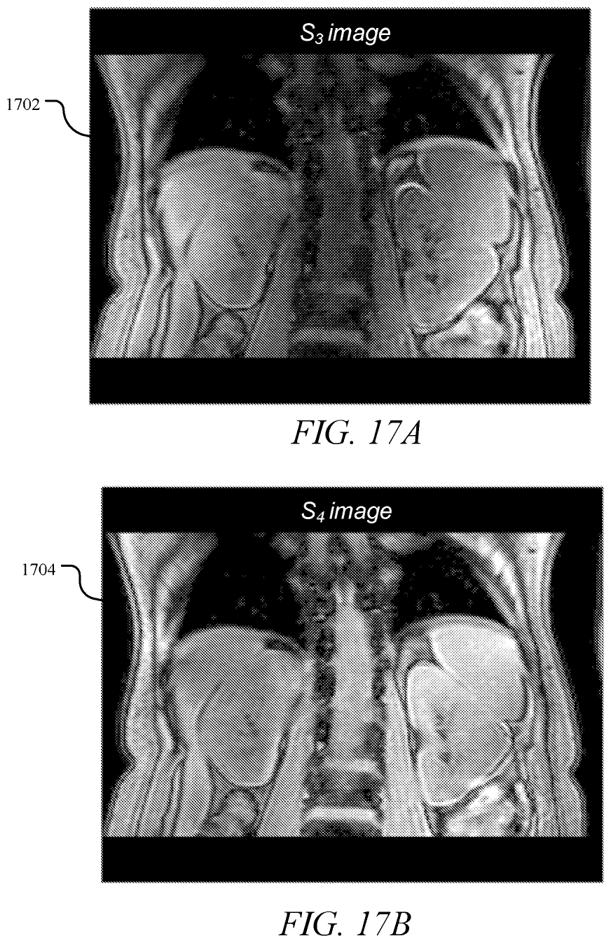

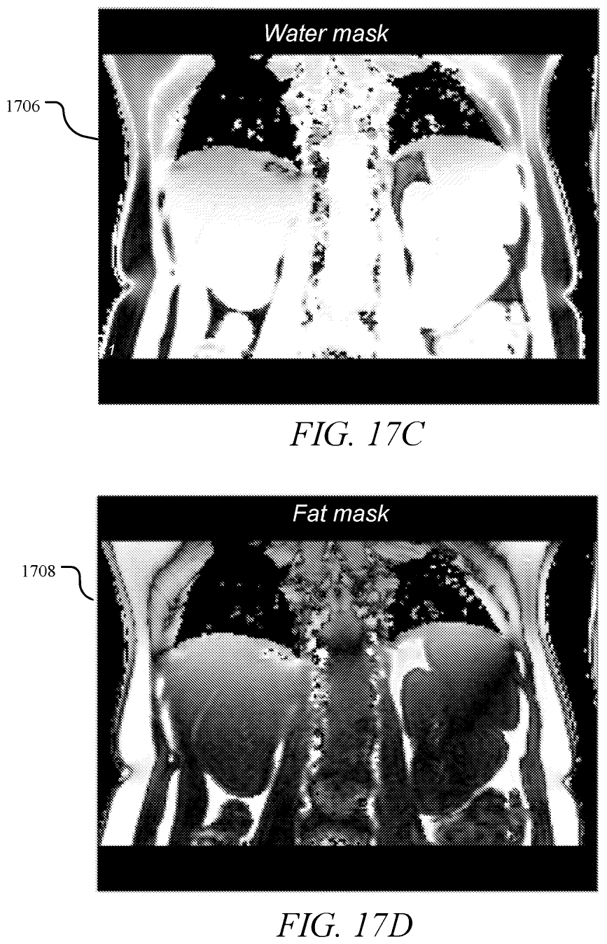

FIGS. 17A and 17B respectively illustrate an S₃ image 1702 and an S₄ image 1704 for the Bilateral Orthogonality Generative Acquisitions method.

FIGS. 17C and 17D respectively illustrate a water mask 1706 and a fast mask 1708 corresponding to the kidney images (i.e., the S₃ image 1702 and the S₄ image 1704) shown in FIGS. 17A and 17B.

Using the sequence 1600 and sequence 1640 homogeneous

$${T}_{2}^{*}$$

images can be obtained and

$${R}_{2}^{*}$$

can be estimated. FIG. 17A and FIG. 17B respectively illustrate the single-channel images S₃ and S₄ (which are from echo 1, i.e., the shortest TE), and these are used for obtaining the homogeneous images in combination with S₁ and S₂, as discussed above. Calculated water only and fat only masks for Dixon imaging are presented in FIG. 17C and FIG. 17D respectively. For these images, a shimming problem can be observed in the left side of the body, which results inaccuracies in the water and fat masks.

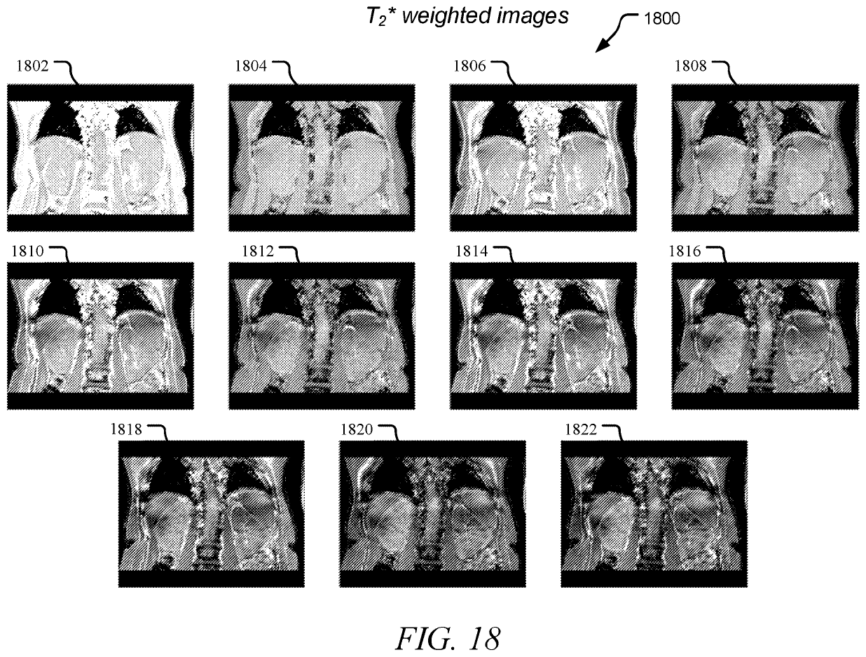

FIG. 18 shows a sequence 1800 including eleven

$${T}_{2}^{*}$$

weighted images (i.e., image 1802, image 1804, image 1806, image 1808, image 1810, image 1812, image 1814, image 1816, image 1818, image 1820, and image 1822). These images show the magnitude of the center slice of the homogeneous

$${T}_{2}^{*}$$

weighted images obtained via Bilateral Orthogonality Generative Acquisitions method with effective echo times of TE_{eff}=2.31−14.41 ms. Further, these images show the magnitude of the homogeneous

$${T}_{2}^{*}$$

images are shown for echoes 2 to 12. Compared to the conventional CP mode images in sequence 1600, the images in sequence 1800 are free of central brightening and present pure

$${T}_{2}^{*}$$

weighted contrast.

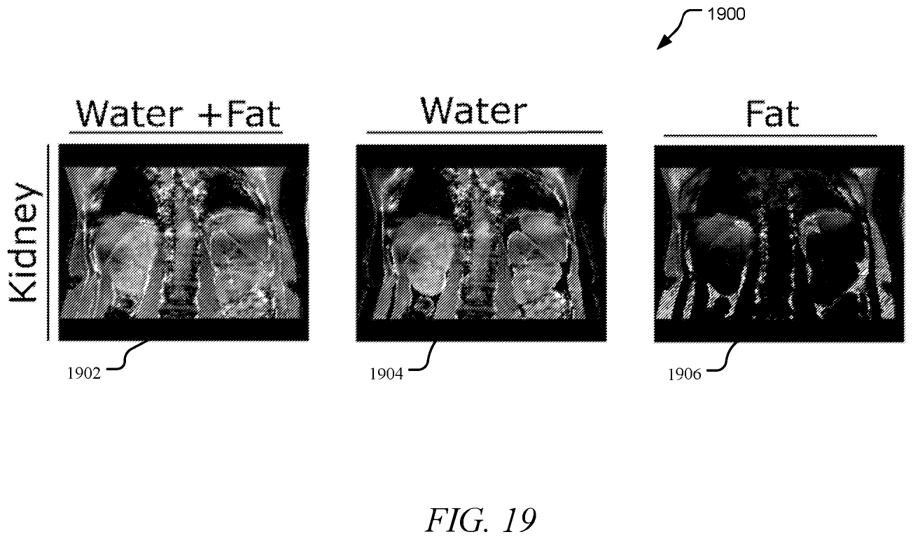

FIG. 19 shows homogeneous

$${T}_{2}^{*}$$

weighted magnitude images for the echo 12 (i.e., TEₑrr=14.41) for the kidneys from the center slice. Image 1902 is shown without Dixon imaging. Image 1904 and image 906 are respectively water only and fat only images. Clear difference between water only and fat only images can be observed for the given

$${T}_{2}^{*}$$

in the image.

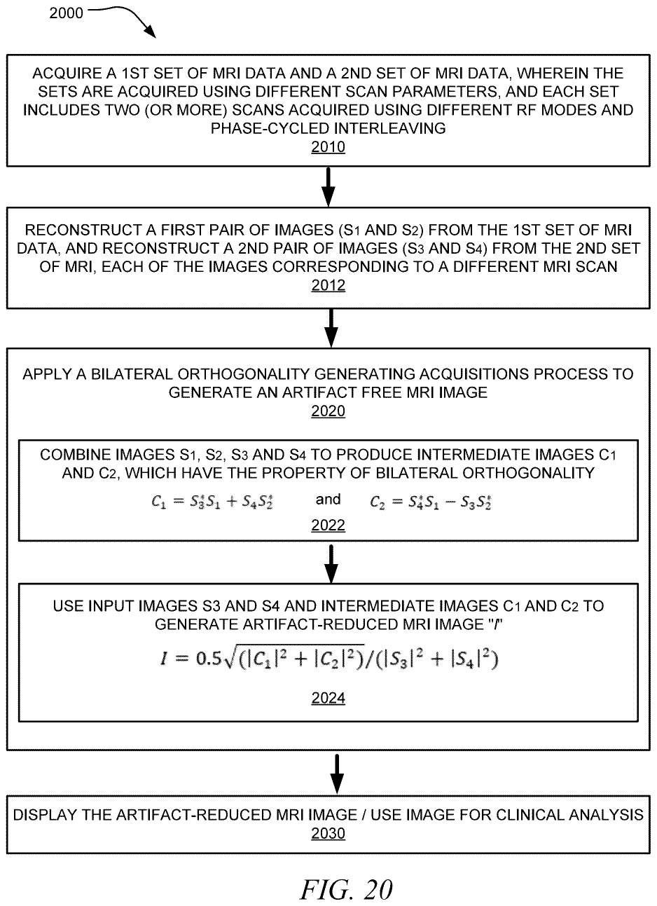

FIG. 20 illustrates another method 2000 for generally using the bilateral orthogonality generating acquisitions method with interleaving for different types of MRI pulse sequences and imaging modalities. Although the method 2000 depicts a particular sequence of operations, the sequence may be altered without departing from the scope of the present disclosure. For example, some of the operations depicted may be performed in parallel or in a different sequence that does not materially affect the function of the routine. In other examples, different components of an example device or system that implements the routine may perform functions at substantially the same time or in a specific sequence.

According to some examples, in step 2010, the method includes acquiring a first set of MRI data and a second set of MRI data using bSSFP mode with interleaving. As discussed above, these sets are acquired using different scan parameters, and each set includes two (or more) scans acquired using different RF modes. In some examples, the two or more scans may be acquired via a dual-channel parallel transmission system. In some examples, the first set of MRI data and the second set of MRI data are two sets of phase-cycled bSSFP data with complimentary excitation patterns and/or RF modes.

In some examples, phase cycle interleaving is used. In this implementation, interleaved N/2 phase-cycled bSSFP images are utilized instead of using N phase-cycled bSSFP images for each RF mode. CP mode phase-cycled bSSFP images may be acquired with phases corresponding to odd-indexed phases in the original N phase cycles, whereas secondary RF mode phase cycled bSSFP images may be acquired with phases corresponding to even-indexed phases in the original N phase cycles. Such a phase cycle interleaving scheme enables utilization of all phase cycles in the multiparametric mapping estimation, without increasing total scan time.

In an example utilizing bSSFP, the two sets are used to individually determine numerator and denominators for the estimation of

$${E}_{1}^{n , i} / {E}_{1}^{d , i} = {e}^{- T R / {T}_{1}} , {E}_{2}^{n , i} / {E}_{2}^{d , i} = {e}^{- T R / {T}_{2}} , and {PD}^{n , i} / {PD}^{d , i} = PD ,$$

where n or d indicates numerator or denominator and i indicates the RF mode.

According to some examples, in step 2012, the method includes reconstructing a first pair of images (S₁ and S₂) from the first set of MRI data, which may be two or more MRI scans. Further, step 2012 includes reconstructing a second pair of images (S₃ and S₄) from the second set of MRI data, which may be two or more MRI scans. Each of these four images corresponds to a different MRI scan that was acquired in step 2010. In some examples utilizing bSSFP, the MRI scans may be reconstructed as S₁=a^{n,1}, S₂=a^{n,2}, S₃=0.5(a^{n,1}−a^{n,2}) and S₄=0.5(a^{n,1}+a^{n,2}), where a may be either E₁, E₂ or PD.

In step 2020, the method includes applying a bilateral orthogonality generating acquisition method to generate an artifact-reduced MRI image. The bilateral orthogonality generating acquisition method uses the space-time diversity provided by the MRI system including multiple receive antennas and performing multiple scans to mitigate undesired signals and/or artifacts from the final MRI image. The MRI images from different scans and different RF receivers are combined to generate an orthogonality between virtual signal channel acquisitions, which can then be combined with other MRI images to mitigate undesired signals and/or artifacts from the final MRI image. Here, phase-cycled bSSFP signals from individual RF phase increments form an ellipse when plotted in a complex plane, which is periodic with 1/TR, making the signals suitable for Fourier analysis. Utilizing Fourier series representation of phase-cycled bSSFP signal profiles and employing algebraic manipulation of the (−1,0,1) Fourier series coefficients derive accurate T₁, T₂, and PD (proton density) images using the numerator and denominator quantities calculated above.

Step 2020 includes steps 2022 and 2024. In step 2022, images S₁, S₂, S₃, and S₄ are utilized to produce intermediate images C₁ and C₂. where

$${C}_{1} = {S}_{3}^{*} {S}_{1} + {S}_{4} {S}_{2}^{*} and {C}_{2} = {S}_{4}^{*} {S}_{1} - {S}_{3} {S}_{2}^{*} ,$$

respectively for bSSFP.

In step 2024, intermediate images C₁ and C₂ and the second pair of images S₃ and S₄ are used to generate an artifact-free MRI image “I.” The artifact-free MRI image can be calculated as I=0.5 \sqrt{(|C₁|²+|C₂|²)}/(℄S₃|²+|S₄|²) where==, C₁ and C₂ are defined as

$${C}_{1} = {S}_{3}^{*} {S}_{1} + {S}_{4} {S}_{2}^{*} and$$

$${C}_{2} = {S}_{4}^{*} {S}_{1} - {S}_{3} {S}_{2}^{*} ,$$

respectively.

According to some examples, in step 2030, the method includes displaying the artifact-reduced MRI image “I” and using this image for clinical analysis.

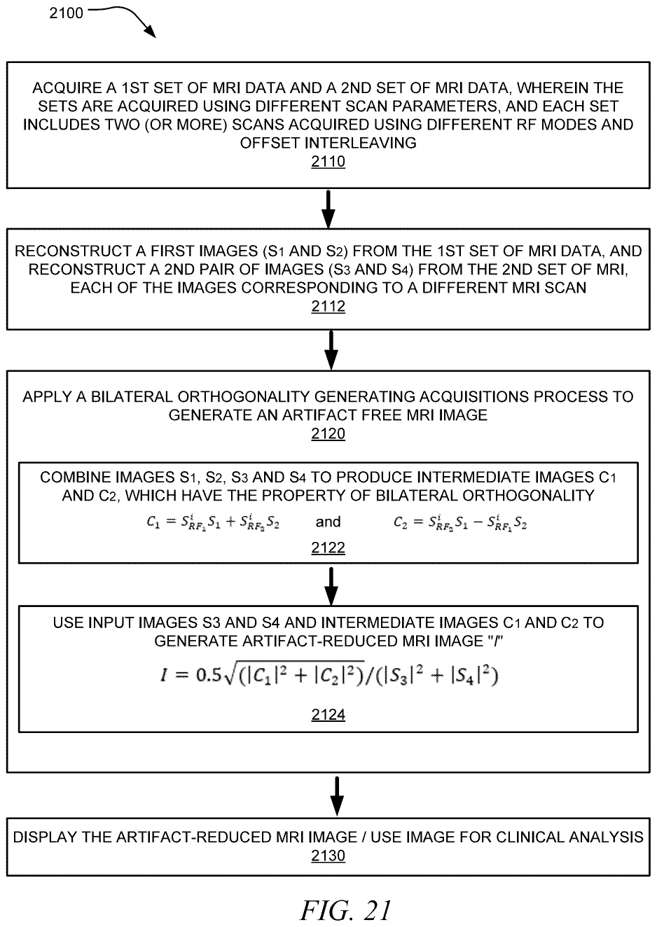

FIG. 21 illustrates another method 2100 for using the bilateral orthogonality generating acquisitions method with interleaving for different types of MRI pulse sequences and imaging modalities. Although the method 2100 depicts a particular sequence of operations, the sequence may be altered without departing from the scope of the present disclosure. For example, some of the operations depicted may be performed in parallel or in a different sequence that does not materially affect the function of the routine. In other examples, different components of an example device or system that implements the routine may perform functions at substantially the same time or in a specific sequence.

According to some examples, in step 2110, the method includes acquiring a first set of MRI data and a second set of MRI data using a Chemical exchange saturation transfer (CEST) mode with interleaving. CEST indicates the effects of metabolic alternation for various pathologies through the simultaneous detection of exchange between water and protons from different metabolite targets.

As discussed above, these sets are acquired using different scan parameters, and each set includes two (or more) scans acquired using different RF modes. In some examples, the two or more scans may be acquired via a dual-channel parallel transmission system. In some examples, the first set of MRI data and the second set of MRI data are two acquisitions or scans with complementary RF modes for each frequency offset. In some examples utilizing CEST, offset interleaving is used when capturing the first set and second set of MRI data, where odd and even-numbered offsets are used for each of the CP mode and the secondary mode, resulting in images with offset values between the original offsets, and the total number of offsets is reduced by 1. A simple mean may be used for determination of offset values when utilizing interleaving.

According to some examples, in step 2112, the method includes reconstructing a first pair of images (S₁ and S₂) from the first set of MRI data. Images obtained from the reference offset are used to calculate single-channel images as

$${S}_{1} = 0.5 ( {S}_{R {F}_{1}}^{ref} - {S}_{R {F}_{2}}^{ref} ) and {S}_{2} = 0.5 ( {S}_{R {F}_{1}}^{ref} + {s}_{R {F}_{2}}^{ref} ) .$$

Further, step 2112 includes reconstructing a second pair of images from the second set of MRI data. The second pair of images is reconstructed as

$${S}_{R {F}_{1}}^{i} , and {S}_{R {F}_{2}}^{i} .$$

According to some examples, in step 2120, the method includes applying a bilateral orthogonality generating acquisition method to generate an artifact-reduced or artifact-free MRI image. Step 2120 includes steps 2122 and 2124. In step 2122, images S₁, S₂,

$${S}_{R {F}_{1}}^{i} , and {S}_{R {F}_{2}}^{i}$$

are utilized to produce intermediate images C₁ and C₂, where

$${C}_{1} = {S}_{R {F}_{1}}^{i} {S}_{1} + {S}_{R {F}_{2}}^{i} {S}_{2} and {C}_{2} = {S}_{R {F}_{2}}^{i} {S}_{1} - {S}_{R {F}_{1}}^{i} {S}_{2} .$$

In step 2124, intermediate images C₁ and C₂ and the second pair of images

$${S}_{R {F}_{1}}^{i} , and {S}_{R {F}_{2}}^{i}$$

are used to generate an artifact-reduced or substantially artifact-free MRI image “I.” The artifact-reduced MRI image can be calculated as I=0.5 \sqrt{(|C₁|²+|C₂|²)}/(|S₃|²+|S₄|²).

According to some examples, in step 2130, the method includes displaying the artifact-free MRI image I and using this image for clinical analysis.

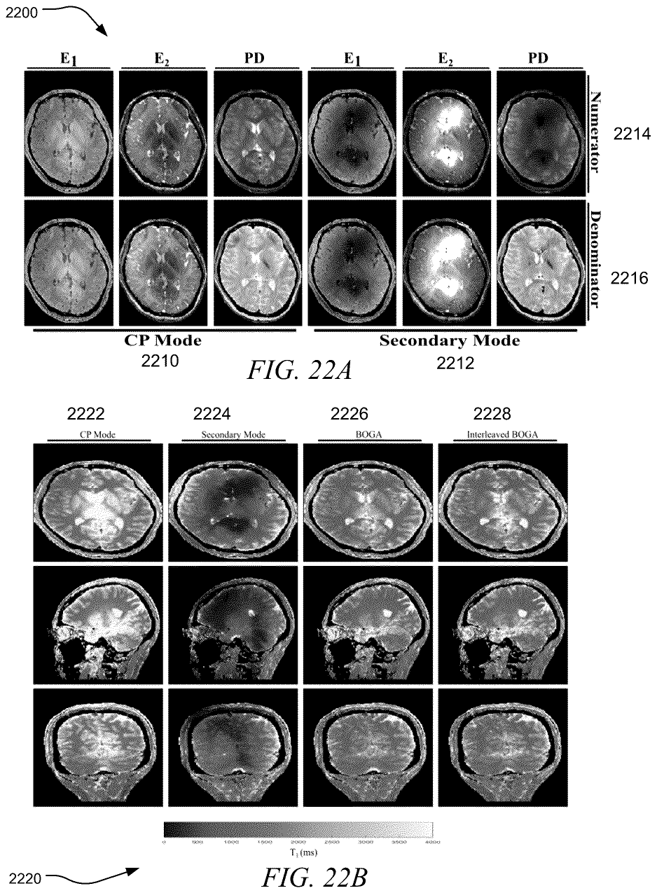

FIG. 22A and FIG. 22B illustrate non-limiting examples of MRI images produced by applying the Bilateral Orthogonality Generating Acquisitions Method to MRI images acquired using balanced steady state free precession (bSSFP) MRI imaging with interleaving, in accordance with some example implementations. In FIG. 22A, a set of images 2200 is shown, including a first set of images 2210 in CP mode for E₁, E₂, and PD, a second set of images 2212 in a Secondary mode, including E₁, E₂, and PD. Referring to FIG. 22A, the depicted numerator 2214 and denominator 2216 quantities used for multi-parametric mapping appear distinct as the first set of images 2210 in CP mode have high intensity at the central region for E₁ and low intensity for E₂, whereas images 2212 in Secondary mode have low intensity at the center for E₁ and high intensity for E₂. This indicates the complimentary nature of the RF modes as high and low intensity regions are shifted in each RF mode. The effects of the

$${B}_{1}^{+}$$

inhomogeneity can be better observed in each numerator 2214 and denominator 2216 quantity.

For the images shown in FIG. 22A and FIG. 22B, the bSSFP acquisitions were acquired with 12 RF phase increments (increasing with 300 with each linear phase increment), each with voxel size of 1×1×1 mm³ to generate a 3D image in which the voxels make up a 224×224×160 acquisition matrix. Further, the images were acquired using a compressed sensitive encoding (SENSE) factor of 6 for each distinct excitation pattern and RF mode. Echo and repetition times were set to 3.35 ms and 6.7 ms with a 10° 20° flip angle. In each set of acquisitions, an echo-time-to-repetition-time ratio of TE_{1/}TR were set to 3.35 ms and 6.7 ms with a 10° 20° flip angle, respectively.

FIG. 22B illustrates T₁ maps obtained via CP mode 2222, Secondary mode 2224, BOGA 2226, and interleaved BOGA 2228 method using phase-cycled bSSFP. The T₁ maps obtained for each RF mode show the residual effects of the

$${B}_{1}^{+}$$

inhomogeneity as over- and underestimation of the parameters corresponding to the high and low intensity regions of the maps, in line with

$${B}_{1}^{+}$$

inhomogeneity effects demonstrated in FIG. 22A. In comparison to T₁ maps for CP mode 2222, the T₁ maps obtained using the BOGA 2226 and interleaved BOGA 2228 method show reduced

$${B}_{1}^{+}$$

effects.

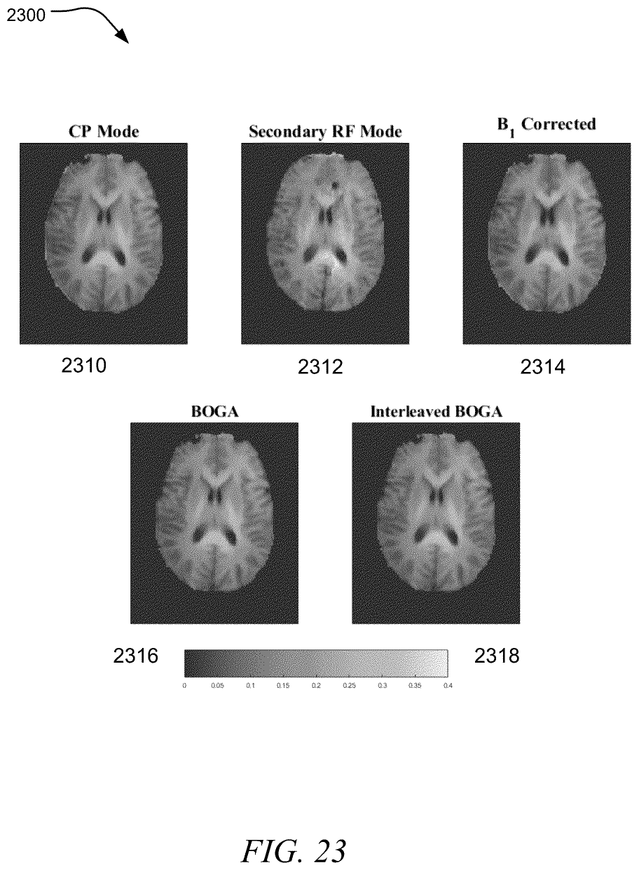

FIG. 23 illustrates a non-limiting example of MRI images 2300 produced by applying the Bilateral Orthogonality Generating Acquisitions Method to MRI images acquired using CEST MRI imaging with interleaving, in accordance with some example implementations. CEST MRI images 2300 are shown, including image 2310 in CP mode, image 2312 in Secondary RF mode, image 2314 in B1 Corrected mode, image 2316 using the BOGA method, and image 2318 using interleaved BOGA.

For the exemplary images shown in FIG. 23, the CEST acquisitions were acquired with a dual-channel transmit head coil integrated with a 32-channel receive coil. CEST acquisitions were performed with 5° flip angle, TR/TE of 4750/16 ms, voxel size of 2×2×10 mm³, TFE factor of 93, a B₁ level of 1.2 μT, and a saturation train duration of 2.4 s. For multi-level 1 level acquisitions, the CP mode may be utilized with 1 levels of 1.2 μT, 0.9 μT, and 0.6 μT. The high-spectral-resolution CEST protocol included 79 frequency offsets sweeping from 20 μm to −20 ppm, with 3 additional offsets at 200 ppm for normalization. The scan time for individual B₁ level and RF mode was 8 minutes, although another number of minutes may be used. However, the disclosure is not limited as such, and any suitable parameters may be used. The images 2300 are depicted with magnetization transfer (MT) effects to highlight the differences and effectiveness among the CP mode image 2310, Secondary RF mode image 2312, B1 Corrected image 2314, BOGA method image 2316, and the BOGA interleaved method image 2318.

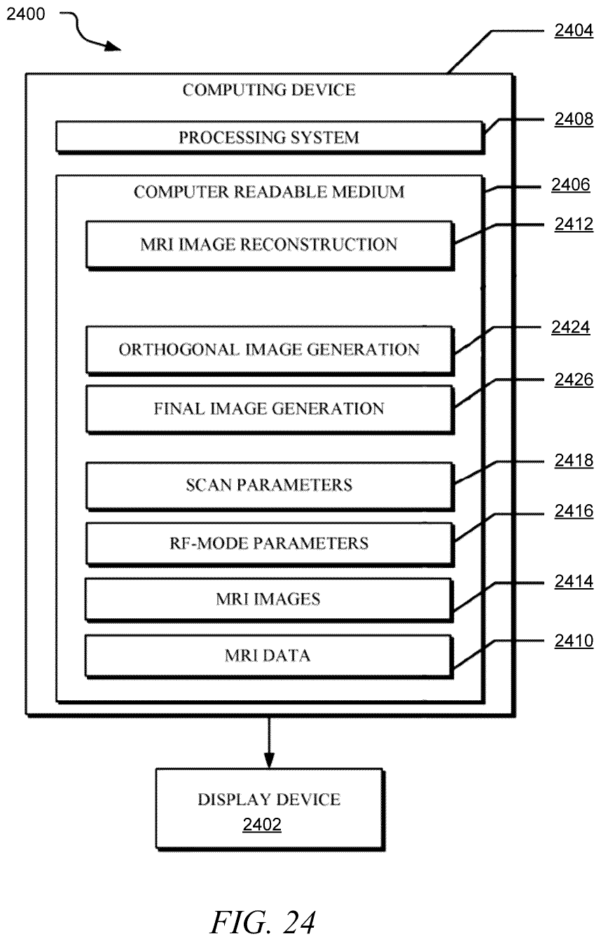

FIG. 24 illustrates a system 2400 that can perform methods 1100, 2000, and 2100, for example. System 2400 can include a display device 2402 and a computing device 2404. The computing device 2404 can include a computer-readable medium 2406 and a processing system 2408 (e.g., one or more processors, such as central processing units (CPU), graphical processing units (GPUs), digital signal processors (DSPs), etc.) that executes instructions stored in the computer-readable medium 2406.

The computer-readable medium 2406 can include various sets of instructions to perform the steps and processes illustrated in FIGS. 10, 11, 20, and 21 and to store the results and inputs for those steps and processes. For example, the computer-readable medium 2406 can store the MRI data 2410 generated by performing an MRI scan and store the scan parameters 2418 and RF-mode parameters 2416 used to perform the scans. The scan parameters 2418 can include various values such as the TFE factor, TSE factor, TE, TR, SENSE factor, the flip angle, etc. Within each set of acquisitions, the scan parameters can be the same (but different between different sets of acquisitions) and the RF-mode parameters 2416 can be different for different acquisitions within a given set of acquisitions. The RF-mode parameters 2416 can be the relative phase values between the excited RF coils/antennas (e.g., within a given set of acquisitions, the first acquisition can use a circular polarized RF mode and the second acquisition can use an RF mode additional phase shift, e.g., π radians, between the excited RF coils/antennas).

Further, the computer-readable medium 2406 can store instructions for MRI image reconstruction 2412 and store the MRI images 2414 generated by performing said instructions for MRI image reconstruction 2412.

Additionally, the computer-readable medium 2406 can store instructions for performing the methods described herein. For instance, the computer-readable medium 2406, includes instructions for performing the orthogonal image generation 2424 and the final image generation 2426. As discussed above, orthogonal image generation 2424 and the final image generation 2426 can be integrated such that the demarcation between them becomes blurred. For example, the vector can be calculated as

$$C = [ \begin{matrix}{C}_{1} \\ {C}_{2}\end{matrix} ] = [ \begin{matrix}{Q}_{1}^{*} & {Q}_{2} \\ {Q}_{2}^{*} & - {Q}_{1}\end{matrix} ] [ \begin{matrix}{S}_{1} \\ {S}_{2}^{*}\end{matrix} ] .$$

such that the images Q₁ and Q₂ are only generated implicitly. Nevertheless, the images Q₁ and Q₂ still play a significant role in determining the final results, even though they are integrated (rather than explicit) in the calculation.

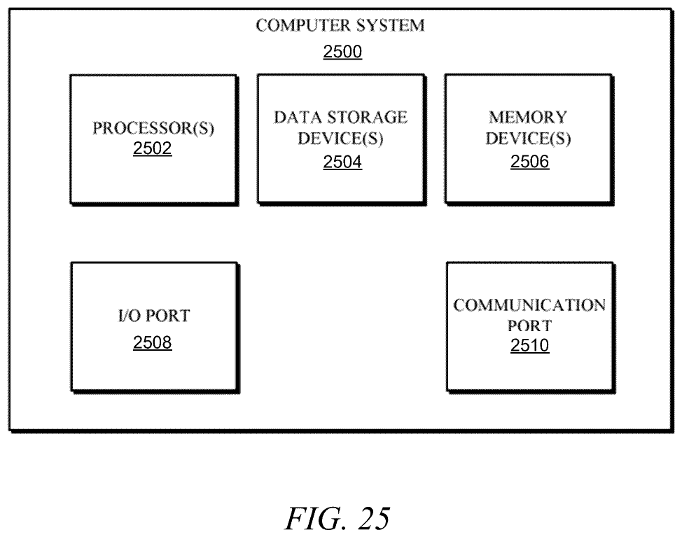

Referring to FIG. 25, a detailed description of an example computing system 2500 having one or more computing units that may implement various systems and methods discussed herein is provided. The computing system 2500 may be applicable to the MRI system 1000, the image reconstruction system 2400, and other computing or network devices. It will be appreciated that specific implementations of these devices may be of differing possible specific computing architectures not all of which are specifically discussed herein but will be understood by those of ordinary skill in the art.

FIG. 25 illustrates an example of another computing system 2500 that can be used to perform the functions of the MRI system 1000 illustrated in FIG. 10 and the steps of method 1100, 2000, 2100, for example, as illustrated in FIG. 11, FIG. 20, and FIG. 21. The computing system 2500 may be a computing system capable of executing a computer program product to execute a computer process. Data and program files may be input to the computing system 2500, which reads the files and executes the programs therein. Some of the elements of the computing system 2500 are shown in FIG. 25, including one or more hardware processors 2502, one or more data storage devices 2504, one or more memory devices 2506, and/or one or more ports 2508-2510. Additionally, other elements that will be recognized by those skilled in the art may be included in the computing system 2500, but are not explicitly depicted in FIG. 25 or discussed further herein. Various elements of the computing system 2500 may communicate with one another by way of one or more communication buses, point-to-point communication paths, or other communication means not explicitly depicted in FIG. 25.

The processor 2502 may include, for example, a central processing unit (CPU), a microprocessor, a microcontroller, a digital signal processor (DSP), and/or one or more internal levels of cache. There may be one or more processors 2502, such that the processor 2502 comprises a single central processing unit, or a plurality of processing units capable of executing instructions and performing operations in parallel with each other, commonly referred to as a parallel processing environment.

The computing system 2500 may be a conventional computer, a distributed computer, or any other type of computer, such as one or more external computers made available via a cloud computing architecture. The presently described technology is optionally implemented in software stored on the data stored device(s) 2504, stored on the memory device(s) 2506, and/or communicated via one or more of the ports 2508-2510, thereby transforming the computing system 2500 in FIG. 25 to a special-purpose machine for implementing the operations described herein. Examples of the computing system 2500 include personal computers, terminals, workstations, mobile phones, tablets, laptops, personal computers, multimedia consoles, gaming consoles, set top boxes, and the like.

The one or more data storage devices 2504 may include any non-volatile data storage device capable of storing data generated or employed within the computing system 2500, such as computer-executable instructions for performing a computer process, which may include instructions of both application programs and an operating system (OS) that manages the various components of the computing system 2500. The data storage devices 2504 may include, without limitation, magnetic disk drives, optical disk drives, solid state drives (SSDs), flash drives, and the like. The data storage devices 2504 may include removable data storage media, non-removable data storage media, and/or external storage devices made available via a wired or wireless network architecture with such computer program products, including one or more database management products, web server products, application server products, and/or other additional soft-ware components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 2506 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 2504 and/or the memory devices 2506, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures. The machine-readable media may store instructions that, when executed by the processor, cause the systems to perform the operations disclosed herein.

In some implementations, the computing system 2500 includes one or more ports, such as an input/output (I/O) port 2508 and a communication port 2510, for communicating with other computing, network, or reservoir development devices. It will be appreciated that the ports 2508-2510 may be combined or separate and that more or fewer ports may be included in the computing system 2500.

The I/O port 2508 may be connected to an I/O device, or other device, by which information is input to or output from the computing system 2500. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 2500 via the I/O port 2508. Similarly, the output devices may convert electrical signals received from computing system 2500 via the I/O port 2508 into signals that may be sensed as output by a human, such as sound, light, and/or touch. The input device may be an alphanumeric input device, including alphanumeric and other keys for communicating information and/or command selections to the processor 2502 via the I/O port 2508. The input device may be another type of user input device including, but not limited to: direction and selection control devices, such as a mouse, a trackball, cursor direction keys, a joystick, and/or a wheel; one or more sensors, such as a camera, a microphone, a positional sensor, an orientation sensor, a gravitational sensor, an inertial sensor, and/or an accelerometer; and/or a touch-sensitive display screen (“touchscreen”). The output devices may include, without limitation, a display, a touchscreen, a speaker, a tactile and/or haptic output device, and/or the like. In some implementations, the input device and the output device may be the same device, for example, in the case of a touchscreen.

In one implementation, a communication port 2510 is connected to a network by way of which the computing system 2500 may receive network data useful in executing the methods and systems set out herein as well as transmitting information and network configuration changes determined thereby. Stated differently, the communication port 2510 connects the computing system 2500 to one or more communication interface devices configured to transmit and/or receive information between the computing system 2500 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 2510 to communicate one or more other machines, either directly over a point-to-point communication path, over a wide area network (WAN) (e.g., the Internet), over a local area network (LAN), over a cellular (e.g., third generation (3G) or fourth generation (4G) or fifth generation (5G) network), or over another communication means. Further, the communication port 2510 may communicate with an antenna or other link for electromagnetic signal transmission and/or reception.

In an example implementation, the various MRI images disclosed herein (e.g., MRI images 2414), instructions for scan parameters (e.g., scan parameters 2418), RF modes (e.g., RF-mode parameters 2416), and software and other modules and services may be embodied by instructions stored on the data storage devices 2504 and/or the memory devices 2506 and executed by the processor 2502. The computing system 2500 may be integrated with or otherwise form part of the MRI system 1000.

The system set forth in FIG. 25 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

In the present disclosure, the methods disclosed may be implemented as sets of instructions or software readable by a device. Further, it is understood that the specific order or hierarchy of steps in the methods disclosed are instances of example approaches. The accompanying method claims present elements of the various steps in a sample order and are not necessarily meant to be limited to the specific order or hierarchy presented.

The described disclosure may be provided as a computer program product, or software, which may include a non-transitory machine-readable medium having stored thereon instructions, which may be used to program a computer system (or other electronic devices) to perform a process according to the present disclosure. A machine-readable medium includes any mechanism for storing information in a form (e.g., software, processing application) readable by a machine (e.g., a computer). The machine-readable medium may include, but is not limited to, magnetic storage medium, optical storage medium; magneto-optical storage medium, read only memory (ROM); random access memory (RAM); erasable programmable memory (e.g., EPROM and EEPROM); flash memory; or other types of medium suitable for storing electronic instructions.

For clarity of explanation, in some instances the present technology may be presented as including individual functional blocks including functional stimulation blocks comprising devices, device components, steps or routines in a method embodied in software, or combinations of hardware and software.

Any of the steps, operations, functions, or processes described herein may be performed or implemented by a combination of hardware and software services or services, alone or in combination with other devices. In some implementations, a service can be software that resides in memory of a client device and/or one or more servers of a content management system and perform one or more functions when a processor executes the software associated with the service. In some implementations, a service is a program, or a collection of programs that carry out a specific function. In some implementations, a service can be considered a server. The memory can be a non-transitory computer-readable medium.

In some implementations the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Methods according to the above-described examples can be implemented using computer-executable instructions that are stored or otherwise available from computer readable media. Such instructions can comprise, for example, instructions and data which cause or otherwise configure a general-purpose computer, special purpose computer, or special purpose processing device to perform a certain function or group of functions. Portions of computer resources used can be accessible over a network. The computer executable instructions may be, for example, binaries, intermediate format instructions such as assembly language, firmware, or source code. Examples of computer-readable media that may be used to store instructions, information used, and/or information created during methods according to described examples include magnetic or optical disks, solid state memory devices, flash memory, USB devices provided with non-volatile memory, networked storage devices, and so on.

Devices implementing methods according to these disclosures can comprise hardware, firmware and/or software, and can take any of a variety of form factors. Typical examples of such form factors include servers, laptops, smart phones, small form factor personal computers, personal digital assistants, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are means for providing the functions described in these disclosures.

Although a variety of examples and other information was used to explain aspects within the scope of the appended claims, no limitation of the claims should be implied based on particular features or arrangements in such examples, as one of ordinary skill would be able to use these examples to derive a wide variety of implementations. Further and although some subject matter may have been described in language specific to examples of structural features and/or method steps, it is to be understood that the subject matter defined in the appended claims is not necessarily limited to these described features or acts. For example, such functionality can be distributed differently or performed in components other than those identified herein. Rather, the described features and steps are disclosed as examples of components of systems and methods within the scope of the appended claims.

What is claimed is:

1. A method of reducing artifacts in MRI images, the method comprising:
acquiring a first set of MRI data including a first MRI scan with first scan parameters and a first radiofrequency (RF) mode, and a second MRI scan with the first scan parameters and a second RF mode;
acquiring a second set of MRI data including a third MRI scan with second scan parameters and a third RF mode, and a fourth MRI scan with the second scan parameters and a fourth RF mode;
reconstructing a first MRI image S₁ and a second MRI image S₂ with the first set of MRI data;
reconstructing a third MRI image S₃ and a fourth MRI image S₄ with the second set of MRI data; and
generating a combined MRI image I from the first MRI image S₁, the second MRI image S₂, the third MRI image S₃, and the fourth MRI image S₄.

2. The method of claim 1, wherein generating the combined MRI image I includes:
generating a pair of intermediate images using the first MRI image S₁, the second MRI image S₂, the third MRI image S₃, and the fourth MRI image S₄ to combine the first set of MRI data and the second set of MRI data, wherein the pair of intermediate images is generated to have a bilateral orthogonality relation; and
generating the combined MRI image I from the pair of intermediate images.

3. The method of claim 1, wherein the first RF mode is a same mode as the third RF mode, the second RF mode is a same mode as the fourth RF mode, the first RF mode is different from the second RF mode, and the third RF mode is different from the fourth RF mode.

4. The method of claim 1, wherein an MRI mode and pulse sequence used for acquiring the first set of MRI data and the second set of MRI data is selected from a group consisting of balanced steady state free precession (bSSFP) MRI imaging and Chemical exchange saturation transfer (CEST) imaging.

5. The method of claim 1, wherein reconstructing the first MRI image S₁, the second MRI image S₂, the third MRI image S₃, and the fourth MRI image S₄ includes:
calculating estimations and proton density for the first set of MRI data and the second set of MRI data; and
generating the combined MRI image I includes using the estimations and the proton density of the first set of MRI data and the second set of MRI data.

6. The method of claim 1, wherein reconstructing the first MRI image S₁, the second MRI image S₂, the third MRI image S₃, and the fourth MRI image S₄ includes:
calculating numerator and denominator images using longitudinal magnetization time constant (T1), transverse relaxation time (T2), and proton density of the first set of MRI data and the second set of MRI data; and
generating the combined MRI image I includes mapping the T1, T2, and proton density of the first set of MRI data and the second set of MRI data.

7. The method of claim 1, wherein reconstructing the first MRI image S₁, the second MRI image S₂, the third MRI image S₃, and the fourth MRI image S₄ includes:
calculating numerator and denominator images using longitudinal magnetization time constant T1, transverse relaxation time (T2), and proton density of the first set of MRI data and the second set of MRI data; and
generating the combined MRI image I includes generating the combined MRI image I as a ratio of squared intensity sums from the numerator images to the denominator images.

8. The method of claim 5, wherein generating of the combined MRI image I includes:
calculating a pair of intermediary results from the first MRI scan, the second MRI scan, the third MRI scan, and the fourth MRI scan; and
generating the combined MRI image I includes using the pair of intermediary results, the first MRI image S₁, the second MRI image S₂, the third MRI image S₃, and the fourth MRI image S₄.

9. The method of claim 1, wherein reconstructing the first MRI image S₁, the second MRI image S₂, the third MRI image S₃, and the fourth MRI image S₄ includes:
calculating virtual single-channel acquisition images via linear combinations using the first MRI scan, the second MRI scan, the third MRI scan, and the fourth MRI scan; and
calculating a pair of intermediary results using the virtual single-channel acquisition images; and
generating the combined MRI image I includes using the intermediary results, the first MRI image S₁, the second MRI image S₂, the third MRI image S₃, and the fourth MRI image S₄.

10. The method of claim 1, wherein the first, second, third, and fourth MRI scans are acquired using interleaving.

11. The method of claim 10, wherein the interleaving is phase-cycled interleaving, and the first set of MRI data is acquired with phases corresponding to odd-indexed phases and the second set of MRI data is acquired with phases corresponding to even-indexed phases.

12. The method of claim 10, wherein the interleaving is offset interleaving, and the first set of MRI data is acquired with odd numbered offsets and the second set of MRI data is acquired with even numbered offsets.

13. The method of claim 1, wherein generating the combined MRI image I includes:
calculating an intermediary result as
$$C = [ \begin{matrix}{C}_{1} \\ {C}_{2}\end{matrix} ] = [ \begin{matrix}{S}_{3}^{*} & {S}_{4} \\ {S}_{4}^{*} & - {S}_{3}\end{matrix} ] [ \begin{matrix}{S}_{1} \\ {S}_{2}^{*}\end{matrix} ] ;$$
and
calculating the combined MRI image I as
$$I = \sqrt{0.5 {C}^{H} C} / ( {S}_{3}^{*} {S}_{3} + {S}_{4}^{*} {S}_{4} ) .$$

14. The method of claim 1, wherein generating the combined MRI image I includes:
calculating virtual single channel acquisition images Q₁ and Q₂, as Q₁=−0.5(S₃−S₄) and Q₂=0.5(S₃+S₄),
calculating an intermediary result as
$$C = [ \begin{matrix}{C}_{1} \\ {C}_{2}\end{matrix} ] = [ \begin{matrix}{Q}_{1}^{*} & {Q}_{2} \\ {Q}_{2}^{*} & - {Q}_{1}\end{matrix} ] [ \begin{matrix}{S}_{1} \\ {S}_{2}^{*}\end{matrix} ] ;$$
and
calculating the combined MRI image I as
$$I = \sqrt{0.5 {C}^{H} C} / ( {Q}_{1}^{*} {Q}_{1} + {Q}_{2}^{*} {Q}_{2} ) .$$

15. The method of claim 1, wherein generating the combined MRI image I includes:
calculating a first intermediary result as
$$C = [ \begin{matrix}{C}_{1} \\ {C}_{2}\end{matrix} ] = [ \begin{matrix}{Q}_{1}^{*} & {Q}_{2} \\ {Q}_{2}^{*} & - {Q}_{1}\end{matrix} ] [ \begin{matrix}{S}_{1} \\ {S}_{2}^{*}\end{matrix} ] ;$$
calculating a second intermediary result as
$$D = [ \begin{matrix}{D}_{1} \\ {D}_{2}\end{matrix} ] = [ \begin{matrix}{Q}_{1} & - {Q}_{2} \\ {Q}_{2}^{*} & {Q}_{1}\end{matrix} ] [ \begin{matrix}{S}_{1} \\ {S}_{2}^{*}\end{matrix} ] ;$$
and
calculating the combined MRI image I as I=F/E,
$$E = ( {Q}_{1}^{*} {Q}_{1} + {Q}_{2}^{*} {Q}_{2} ) ,$$
where F=0.25 (C₁+Dᵢ+C₂+D₂+(C₁−D₁+C₂−D₂)*).

16. The method of claim 1, wherein generating the combined MRI image I includes:
generating a pair of intermediate complex T₂* weighted images using the first MRI image S₁, the second MRI image S₂, the third MRI image S₃, and the fourth MRI image S₄ to combine the first set of MRI data and the second set of MRI data; and
generating the combined MRI image I from the pair of intermediate complex T₂* weighted images by removing effects based on
$$Δ {B}_{1}^{+}$$
at a final
$${T}_{2}^{*}$$
magnitude.

17. A computing apparatus comprising:
a processor; and
a memory storing instructions that, when executed by the processor, configure the computing apparatus to:
acquire a first set of MRI data including a first MRI scan with first scan parameters and a first radiofrequency (RF) mode, and a second MRI scan with the first scan parameters and a second RF mode;
acquire a second set of MRI data including a third MRI scan with second scan parameters and a third RF mode, and a fourth MRI scan with the second scan parameters and a fourth RF mode;
reconstruct a first MRI image S₁ and a second MRI image S₂ with the first set of MRI data;
reconstruct a third MRI image S₃ and a fourth MRI image S₄ with the second set of MRI data; and
generate a combined MRI image I from the first MRI image S₁, the second MRI image S₂, the third MRI image S₃, and the fourth MRI image S₄.

18. The computing apparatus of claim 17, wherein the instructions, when executed by the processor, configure the apparatus to generate the combined MRI image by:
generating a pair of intermediate images using the first MRI image S₁, the second MRI image S₂, the third MRI image S₃, and the fourth MRI image S₄ to combine the first set of MRI data and the second set of MRI data, wherein the pair of intermediate images is generated to have a bilateral orthogonality relation; and
generating the combined MRI image from the pair of intermediate images.

19. The computing apparatus of claim 17, wherein an MRI mode and pulse sequence used for acquiring the first set of MRI data and the second set of MRI data is selected from a group consisting of balanced steady state free precession (bSSFP) MRI imaging and Chemical exchange saturation transfer (CEST) imaging.

20. The computing apparatus of claim 17, wherein reconstructing the first MRI image S₁, the second MRI image S₂, the third MRI image S₃, and the fourth MRI image S₄ includes:
calculating estimations and proton density for the first set of MRI data and the second set of MRI data; and
generating the combined MRI image I includes using the estimations and proton density of the first set of MRI data and the second set of MRI data.

21. The computing apparatus of claim 17, wherein reconstructing the first MRI image S₁, the second MRI image S₂, the third MRI image S₃, and the fourth MRI image S₄ includes:
calculating numerator and denominator images using longitudinal magnetization time constant (T1), transverse relaxation time (T2), and proton density of the first set of MRI data and the second set of MRI data; and
generating the combined MRI image I includes mapping the T1, T2, and proton density of the first set of MRI data and the second set of MRI data.

22. The computing apparatus of claim 17, wherein reconstructing the first MRI image S₁, the second MRI image S₂, the third MRI image S₃, and the fourth MRI image S₄ includes:
calculating numerator and denominator images using longitudinal magnetization time constant T1, transverse relaxation time (T2), and proton density of the first set of MRI data and the second set of MRI data; and
generating the combined MRI image I includes generating the combined MRI image I as a ratio of squared intensity sums from the numerator images to the denominator images.

23. The computing apparatus of claim 17, wherein generating of the combined MRI image I includes:
calculating a pair of intermediary results from the first MRI scan, the second MRI scan, the third MRI scan, and the fourth MRI scan; and
generating the combined MRI image I includes using the pair of intermediary results, the first MRI image S₁, the second MRI image S₂, the third MRI image S₃, and the fourth MRI image S₄.

24. The computing apparatus of claim 17, wherein reconstructing the first MRI image S₁, the second MRI image S₂, the third MRI image S₃, and the fourth MRI image S₄ includes:
calculating virtual single-channel acquisition images via linear combinations using the first MRI scan, the second MRI scan, the third MRI scan, and the fourth MRI scan; and
calculating a pair of intermediary results using the virtual single-channel acquisition images; and
generating the combined MRI image I includes using the intermediary results, the first MRI image S₁, the second MRI image S₂, the third MRI image S₃, and the fourth MRI image S₄.

25. The computing apparatus of claim 17, wherein the first, second, third, and fourth MRI scans are acquired using interleaving.

26. The computing apparatus of claim 25, wherein the interleaving is phase-cycled interleaving, and the first set of MRI data is acquired with phases corresponding to odd-indexed phases and the second set of MRI data is acquired with phases corresponding to even-indexed phases.

27. The computing apparatus of claim 25, wherein the interleaving is offset interleaving, and the first set of MRI data is acquired with odd-numbered offsets and the second set of MRI data is acquired with even-numbered offsets.

28. The computing apparatus of claim 17, wherein the instructions, when executed by the processor, configure the apparatus to generate the combined MRI image by:
calculating an intermediary result as
$$C = [ \begin{matrix}{C}_{1} \\ {C}_{2}\end{matrix} ] = [ \begin{matrix}{S}_{3}^{*} & {S}_{4} \\ {S}_{4}^{*} & - {S}_{3}\end{matrix} ] [ \begin{matrix}{S}_{1} \\ {S}_{2}^{*}\end{matrix} ] ;$$
and
calculating the combined MRI image I as
$$I = \sqrt{0.5 {C}^{H} C} / ( {S}_{3}^{*} {S}_{3} + {S}_{4}^{*} {S}_{4} ) .$$

29. The computing apparatus of claim 17, wherein the instructions, when executed by the processor, configure the apparatus to generate the combined MRI image by:
calculating virtual single channel acquisition images Q₁ and Q₂, as Q₁=−0.5(S₃−S₄) and Q₂=0.5(S₃+S₄);
calculating an intermediary result as
$$C = [ \begin{matrix}{C}_{1} \\ {C}_{2}\end{matrix} ] = [ \begin{matrix}{Q}_{1}^{*} & {Q}_{2} \\ {Q}_{2}^{*} & - {Q}_{1}\end{matrix} ] [ \begin{matrix}{S}_{1} \\ {S}_{2}^{*}\end{matrix} ] ;$$
and
calculating the combined MRI image I as
$$I = \sqrt{0.5 {C}^{H} C} / ( {Q}_{1}^{*} {Q}_{1} + {Q}_{2}^{*} {Q}_{2} ) .$$

30. The computing apparatus of claim 17, wherein the instructions, when executed by the processor, configure the apparatus to generate the combined MRI image by:
calculating a first intermediary result as
$$C = [ \begin{matrix}{C}_{1} \\ {C}_{2}\end{matrix} ] = [ \begin{matrix}{Q}_{1}^{*} & {Q}_{2} \\ {Q}_{2}^{*} & - {Q}_{1}\end{matrix} ] [ \begin{matrix}{S}_{1} \\ {S}_{2}^{*}\end{matrix} ] ;$$
calculating a second intermediary result as
$$D = [ \begin{matrix}{D}_{1} \\ {D}_{2}\end{matrix} ] = [ \begin{matrix}{Q}_{1}^{*} & - {Q}_{2} \\ {Q}_{2}^{*} & {Q}_{1}\end{matrix} ] [ \begin{matrix}{S}_{1} \\ {S}_{2}^{*}\end{matrix} ] ;$$
and
calculating the combined MRI image I as I=F/E,
$$E = ( {Q}_{1}^{*} {Q}_{1} + {Q}_{2}^{*} {Q}_{2} ) ,$$
where F=0.25 (C₁+D₁+C₂+D₂+(C₁−D₁+C₂−D₂)*).

31. The computing apparatus of claim 17, wherein the instructions, when executed by the processor, configure the apparatus to generate the combined MRI image by:
generating a pair of intermediate complex T₂* weighted images using the first MRI image S₁, the second MRI image S₂, the third MRI image S₃, and the fourth MRI image S₄ to combine the first set of MRI data and the second set of MRI data; and
generating the combined MRI image I from the pair of intermediate complex T₂* weighted images by removing effects based on
$$Δ {B}_{1}^{+}$$
at a final
$${T}_{2}^{*}$$
magnitude.

32. A non-transitory computer-readable storage medium including instructions that when executed by a computer, cause the computer to:
acquire a first set of MRI data including a first MRI scan with first scan parameters and a first radiofrequency (RF) mode, and a second MRI scan with the first scan parameters and a second RF mode;
acquire a second set of MRI data including a third MRI scan with second scan parameters and a third RF mode, and a fourth MRI scan with the second scan parameters and a fourth RF mode;
reconstruct a first MRI image S₁ and a second MRI image S₂ with the first set of MRI data;
reconstruct a third MRI image S₃ and a fourth MRI image S₄ with the second set of MRI data; and
generate a combined MRI image I from the first MRI image S₁, the second MRI image S₂, the third MRI image S₃, and the fourth MRI image S₄.

33. The non-transitory computer-readable storage medium of claim 32, wherein the instructions cause the computer to acquire the first, second, third, and fourth MRI scans using interleaving.

34. The non-transitory computer-readable storage medium of claim 33, wherein the interleaving is phase-cycled interleaving, and the first set of MRI data is acquired with phases corresponding to odd-indexed phases and the second set of MRI data is acquired with phases corresponding to even-indexed phases.

35. The non-transitory computer-readable storage medium of claim 33, wherein the interleaving is offset interleaving, and the first set of MRI data is acquired with odd-numbered offsets and the second set of MRI data is acquired with even-numbered offsets.

36. The non-transitory computer-readable storage medium of claim 32, wherein reconstructing the first MRI image S₁, the second MRI image S₂, the third MRI image S₃, and the fourth MRI image S₄ includes:
calculating estimations and proton density for the first set of MRI data and the second set of MRI data; and
generating the combined MRI image I includes using the estimations and proton density of the first set of MRI data and the second set of MRI data.

37. The non-transitory computer-readable storage medium of claim 32, wherein reconstructing the first MRI image S₁, the second MRI image S₂, the third MRI image S₃, and the fourth MRI image S₄ includes:
calculating numerator and denominator images using longitudinal magnetization time constant (T1), transverse relaxation time (T2), and proton density of the first set of MRI data and the second set of MRI data; and
generating the combined MRI image I includes mapping the T1, T2, and proton density of the first set of MRI data and the second set of MRI data.

38. The non-transitory computer-readable storage medium of claim 32, wherein reconstructing the first MRI image S₁, the second MRI image S₂, the third MRI image S₃, and the fourth MRI image S₄ includes:
calculating numerator and denominator images using longitudinal magnetization time constant T1, transverse relaxation time (T2), and proton density of the first set of MRI data and the second set of MRI data; and
generating the combined MRI image I includes generating the combined MRI image I as a ratio of squared intensity sums from the numerator images to the denominator images.

39. The non-transitory computer-readable storage medium of claim 32, wherein generating of the combined MRI image I includes:
calculating a pair of intermediary results from the first MRI scan, the second MRI scan, the third MRI scan, and the fourth MRI scan; and
generating the combined MRI image I includes using the pair of intermediary results, the first MRI image S₁, the second MRI image S₂, the third MRI image S₃, and the fourth MRI image S₄.

40. The non-transitory computer-readable storage medium of claim 32, wherein reconstructing the first MRI image S₁, the second MRI image S₂, the third MRI image S₃, and the fourth MRI image S₄ includes:
calculating virtual single-channel acquisition images via linear combinations using the first MRI scan, the second MRI scan, the third MRI scan, and the fourth MRI scan; and
calculating a pair of intermediary results using the virtual single-channel acquisition images; and
generating the combined MRI image I includes using the intermediary results, the first MRI image S₁, the second MRI image S₂, the third MRI image S₃, and the fourth MRI image.

41. The non-transitory computer-readable storage medium of claim 32, wherein the instructions cause the computer to generate the combined MRI image I by:
calculating an intermediary result as
$$C = [ \begin{matrix}{C}_{1} \\ {C}_{2}\end{matrix} ] = [ \begin{matrix}{S}_{3}^{*} & {S}_{4} \\ {S}_{4}^{*} & - {S}_{3}\end{matrix} ] [ \begin{matrix}{S}_{1} \\ {S}_{2}^{*}\end{matrix} ] ;$$
and
calculating the combined MRI image I as
$$I = \sqrt{0.5 {C}^{H} C} / ( {S}_{3}^{*} {S}_{3} + {S}_{4}^{*} {S}_{4} ) .$$

42. The non-transitory computer-readable storage medium of claim 32, wherein the instructions cause the computer to generate the combined MRI image I by:
calculating virtual single channel acquisition images Q₁ and Q₂, as Q₁=−0.5(S₃−S₄) and Q₂=0.5(S₃+S₄);
calculating an intermediary result as
$$C = [ \begin{matrix}{C}_{1} \\ {C}_{2}\end{matrix} ] = [ \begin{matrix}{Q}_{1}^{*} & {Q}_{2} \\ {Q}_{2}^{*} & - {Q}_{1}\end{matrix} ] [ \begin{matrix}{S}_{1} \\ {S}_{2}^{*}\end{matrix} ] ;$$
and
calculating the combined MRI image I as
$$I = \sqrt{0.5 {C}^{H} C} / ( {Q}_{1}^{*} {Q}_{1} + {Q}_{2}^{*} {Q}_{2} ) .$$

43. The non-transitory computer-readable storage medium of claim 32, wherein the instructions cause the computer to generate the combined MRI image I by:
calculating a first intermediary result as
$$C = [ \begin{matrix}{C}_{1} \\ {C}_{2}\end{matrix} ] = [ \begin{matrix}{Q}_{1}^{*} & {Q}_{2} \\ {Q}_{2}^{*} & - {Q}_{1}\end{matrix} ] [ \begin{matrix}{S}_{1} \\ {S}_{2}^{*}\end{matrix} ] ;$$
calculating a second intermediary result as
$$D = [ \begin{matrix}{D}_{1} \\ {D}_{2}\end{matrix} ] = [ \begin{matrix}{Q}_{1}^{*} & {Q}_{2} \\ {Q}_{2}^{*} & - {Q}_{1}\end{matrix} ] [ \begin{matrix}{S}_{1} \\ {S}_{2}^{*}\end{matrix} ] ;$$
and
calculating the combined MRI image I as I=F/E,
$$E = ( {Q}_{1}^{*} {Q}_{1} + {Q}_{2}^{*} {Q}_{2} ) ,$$
where F=0.25 (C₁+D₁+C₂+D₂+(C₁−D₁+C₂−D2)*).

44. The non-transitory computer-readable storage medium of claim 32, wherein the instructions cause the computer to generate the combined MRI image I by:
generating a pair of intermediate complex T₂* weighted images using the first MRI image S₁, the second MRI image S₂, the third MRI image S₃, and the fourth MRI image S₄ to combine the first set of MRI data and the second set of MRI data; and
generating the combined MRI image I from the pair of intermediate complex T₂* weighted images by removing effects for
$$Δ {B}_{1}^{+}$$
at a final
$${T}_{2}^{*}$$
magnitude.
